(19) United States
(12) Patent Application Publication
(10) Pub. No.: US 2020/0052005 A1
(43) Pub. Date: Feb. 13, 2020

(54) DRIVE CIRCUIT, MATRIX SUBSTRATE, AND DISPLAY DEVICE

(71) Applicant: Sharp Kabushiki Kaisha, Sakai City, Osaka (JP)

(72) Inventor: Masahiro YOSHIDA, Sakai City (JP)

(21) Appl. No.: 16/485,832

(22) PCT Filed: Feb. 16, 2018
(86) PCT No.: PCT/JP2018/005567

§ 371 Date: Aug. 14, 2019

(30) Foreign Application Priority Data
Feb. 23, 2017 (JP) 2017-032662

(51) Int. Cl. H01L 27/12; G02F 1/1345; G02F 1/1368; G02F 1/1362

(52) U.S. Cl. CPC H01L 27/1244; G02F 1/13454; G02F 1/1339; G02F 1/136286; G02F 1/1368

(57) ABSTRACT

A drive circuit having a high degree of freedom in arrangement of a first-type wire that connects unit circuits is achieved. Electrodes of transistors (Tr6.1 and Tr6.2) connected in parallel and a bonding wire that connects the electrodes are formed by a gate layer and a source layer. A first relay wire (66) and a second relay wire (67) are formed by an additional wire layer and overlapped with one (Tr6.1) of the transistors. An initialization wire (68) is formed by the additional wire layer and overlapped with the bonding wire.

### TECHNICAL FIELD

The present invention relates to a drive circuit, and particularly relates to a matrix substrate in which a drive circuit is monolithically formed and a display device using the matrix substrate.

### BACKGROUND ART

In small-to-medium-sized display devices, a Gate Driver Monolithic (GDM) technique of monolithically forming a scanning line drive circuit (gate driver) in a matrix substrate has been recently adopted for cost reduction. For example, PTLs 1 to 3 disclose a display device using an active matrix substrate that includes (i) a display region where pixel transistors are arranged and (ii) a peripheral region where a scanning line drive circuit and a source drive circuit that drive the pixel transistors are arranged.

Further, the small-to-medium-sized display devices also have more enhanced definition. Thus, a vertical width (a width in a direction in which a data signal line extends) of a unit circuit that forms the scanning line drive circuit becomes narrower with a pixel pitch. Furthermore, as a frame size is further reduced, it is also difficult to enlarge a horizontal width (a width in a direction in which a scanning line extends) of a region where the scanning line drive circuit is formed. Thus, the scanning line drive circuit is required to have a smaller area. In order to reduce an area of the unit circuit that forms the scanning line drive circuit, PTL 1 discloses a configuration in which a branch wire through which a transistor and a trunk wire that are included in the unit circuit are connected does not need to circumvent the transistor which is not connected. Further, PTL 2 discloses a configuration in which three wires of the unit circuit are able to be overlapped with each other in the same region.

As the definition is enhanced, thinning of a drawn wire from the scanning line drive circuit is also proceeding. Thus, mechanical strength of the drawn wire is lowered and the drawn wire is easily broken. PTL 3 discloses a configuration in which stress concentration on a drawn wire is prevented to prevent the drawn wire from being broken.

### CITATION LIST

### Patent Literature

PTL 1: Domestic Re-publication of PCT International Publication for Patent Application No. WO2011/030590 (internationally published on Mar. 17, 2011)

PTL 2: Japanese Unexamined Patent Application Publication No. 2002-40962 (published on Feb. 8, 2002)

PTL 3: Japanese Unexamined Patent Application Publication No. 2000-56319 (published on Feb. 25, 2000)

### SUMMARY OF INVENTION

### Technical Problem

However, the scanning line drive circuit as described above has a problem that a degree of freedom in arrangement of a wire, such as a relay wire or an initialization wire, which connects unit circuits is low. This is because such a wire needs to circumvent a circuit element that is not connected.

The invention is made in view of the aforementioned problem and an object thereof is to achieve a drive circuit having a high degree of freedom in arrangement of a first-type wire (such as a relay wire or an initialization wire) which connects unit circuits.

### Solution to Problem

In order to solve the aforementioned problem, a drive circuit according to an aspect of the invention includes: a plurality of unit circuits that drive a plurality of output lines; and a first-type wire that connects the unit circuits and is formed by a first conductive layer, in which at least one of the unit circuits includes a circuit element group, the circuit element group includes a single circuit element that has an electrode formed by (i) a second conductive layer different from the first conductive layer or (ii) a third conductive layer different from the first conductive layer or the second conductive layer or includes (i) a plurality of circuit elements connected in parallel and (ii) a second-type wire that connects an electrode of the circuit element included in the circuit element group to an electrode of another circuit element included in the circuit element group and is formed by the second conductive layer or the third conductive layer, and at least one circuit element group is overlapped or in contact with at least one first-type wire in plan view.

### Advantageous Effects of Invention

According to the configuration of the drive circuit according to the aspect of the invention, the first-type wire that connects the unit circuits is formed by the first conductive layer. Further, (i) the electrode of the circuit element and (ii) the second-type wire that connects the electrodes of the circuit elements included in the same circuit element group are formed by the second conductive layer or the third conductive layer each of which is different from the first conductive layer. Thus, the circuit element group is able to be overlapped or in contact with the first-type wire in plan view. Because overlapping or contact is allowed, the first-type wire does not need to circumvent the circuit element group, and the drive circuit in which a degree of freedom in arrangement of the first-type wire and the circuit element group is high is able to be achieved.

### BRIEF DESCRIPTION OF DRAWINGS

FIG. 1 is a plan view illustrating a schematic configuration of a matrix substrate including scanning line drive circuits according to an embodiment of the invention.

FIG. 2 is a signal view illustrating a schematic configuration of signal potential supplied by a low-potential trunk wire and clock trunk wires illustrated in FIG. 1.

FIG. 3 is a circuit diagram illustrating a schematic circuit configuration of a unit circuit illustrated in FIG. 1.

FIG. 4 is a plan view schematically illustrating circuit arrangement of a scanning line drive circuit illustrated in FIG. 1.

FIG. 5 is a plan view schematically illustrating circuit arrangement of the unit circuit illustrated in FIG. 4.

FIG. 6 is a sectional view taken along a line A-A of FIG. 5.

FIG. 7 is a plan view illustrating a schematic pattern of a gate layer of the scanning line drive circuit illustrated in FIG. 4.

FIG. 8 is a plan view illustrating a schematic pattern of a semiconductor layer of the scanning line drive circuit illustrated in FIG. 4.

FIG. 9 is a plan view illustrating a schematic pattern of a source layer of the scanning line drive circuit illustrated in FIG. 4.

FIG. 10 is a plan view illustrating a schematic pattern of a contact hole of the scanning line drive circuit illustrated in FIG. 4.

FIG. 11 is a plan view illustrating a schematic pattern of an additional wire layer of the scanning line drive circuit illustrated in FIG. 4.

FIG. 12 is a sectional view taken along a line B-B of FIG. 5.

FIG. 13 is a plan view illustrating a schematic configuration of a liquid crystal display panel using the matrix substrate illustrated in FIG. 1.

FIG. 14 is a view in which (a) a scanning line drive circuit of a comparative example and (b) the scanning line drive circuit according to the embodiment of the invention are compared.

FIG. 15 is a plan view schematically illustrating circuit arrangement of a unit circuit according to another embodiment of the invention.

FIG. 16 is a sectional view taken along a line C-C of FIG. 15.

FIG. 17 is a view in which (a) the scanning line drive circuit of the comparative example and (b) a scanning line drive circuit 47 according to another embodiment of the invention are compared.

FIG. 18 is a plan view schematically illustrating circuit arrangement of a unit circuit according to still another embodiment of the invention.

### DESCRIPTION OF EMBODIMENTS

Hereinafter, embodiments of the invention will be specifically described with reference to the drawings. Note that, dimensions, materials, shapes, and relative arrangement of components described in the embodiments are merely examples and should not be considered as limiting the scope of the invention only to them.

### Embodiment 1

Embodiment 1 of the invention will be described in detail below.

### (Configuration of Matrix Substrate)

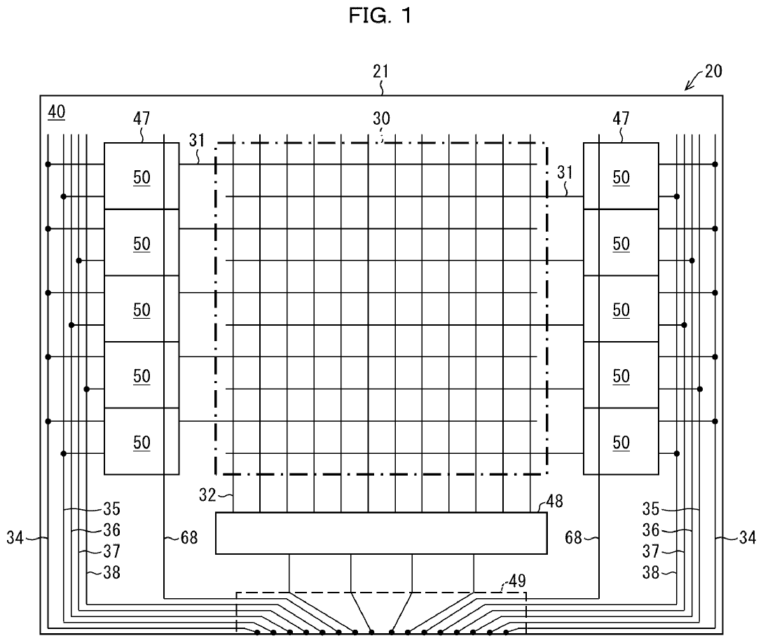

FIG. 1 is a plan view illustrating a schematic configuration of a matrix substrate 20 provided with scanning line drive circuits 47 according to Embodiment 1 of the invention.

As illustrated in FIG. 1, the matrix substrate 20 includes an insulating substrate 21 and the insulating substrate 21 has thereon a display region 30 and a peripheral region 40 other than the display region 30.

In the display region 30, a plurality of scanning lines 31 (output lines) and a plurality of data lines 32 are arranged in a lattice manner. Though not illustrated in FIG. 1, other structures such as a pixel transistor and a pixel electrode are also arranged in the display region 30.

In the peripheral region 40, the scanning line drive circuits 47 (drive circuits) each of which is constituted by a plurality of unit circuits 50 that drive the respective scanning lines 31, a data line drive circuit 48 that drives the respective data lines 32, a terminal portion 49 by which the matrix substrate 20 is connected to outside, wires that extend from the terminal portion 49 to the scanning line drive circuits 47, and wires that extend from the terminal portion 49 to the data line drive circuit 48 are arranged.

The data lines 32 extend in a vertical direction of FIG. 1 and are connected to the data line drive circuit 48 on a lower side. Note that, there is no limitation thereto and a configuration in which the display region 30 is divided into upper and lower parts and data line drive circuits 48 are arranged in the upper and lower parts of the display region 30 may be provided, for example.

The scanning lines 31 extend in a horizontal direction of FIG. 1 and are alternately connected one by one to the scanning line drive circuits 47 on both right and left sides. Note that, there is no limitation thereto and a configuration in which the respective scanning lines 31 are connected to the scanning line drive circuits 47 on both the right and left sides may be provided, for example. Further, for example, a configuration in which a scanning line drive circuit 47 is arranged on either right or left side may be provided.

Each of the scanning line drive circuits 47 according to Embodiment 1 has two shift registers that are combined so as to have cycles shifted. Thus, the matrix substrate 20 according to Embodiment 1 includes four shift registers and the scanning lines 31 connected to the respective shift registers are sequentially driven.

Hereinafter, a total number of scanning lines 31 is defined as N (N: natural number). Further, a unit circuit 50 that drives an nth (n: natural number equal to or less than N) scanning line 31 is defined as a unit circuit 50 on an nth stage. Furthermore, potential that the unit circuit 50 on the nth stage outputs to the nth scanning line 31 is defined as Out(n).

The wires that extend from the terminal portion 49 to the scanning line drive circuit 47 include a low-potential trunk wire 34 (trunk wire) that supplies low potential Vss, a first clock trunk wire 35 that supplies a first clock signal CK1, a second clock trunk wire 36 that supplies a second clock signal CK2, a third clock trunk wire 37 that supplies a third clock signal CK3, a fourth clock trunk wire 38 that supplies a fourth clock signal CK4, an initialization wire 68 (first-type wire) that supplies an initialization signal Reset, and a start trunk wire (not illustrated) that supplies a start signal.

Hereinafter, the first clock trunk wire 35, the second clock trunk wire 36, the third clock trunk wire 37, and the fourth clock trunk wire 38 are collectively referred to as “clock trunk wires 35 to 38”. Further, the first clock signal CK1, the second clock signal CK2, the third clock signal CK3, and the fourth clock signal CK4 are collectively referred to as “clock signals CK1 to CK4”.

In the present specification, a wire that passes through only an outer side of the drive circuit among wires that supply a signal, low potential, high potential, and the like to the drive circuit is referred to as a “trunk wire”. Therefore, the initialization wire 68 illustrated in FIG. 1 passes through also an inner side of the scanning line drive circuit 47 and is thus not referred to as a trunk wire.

### (Signal)

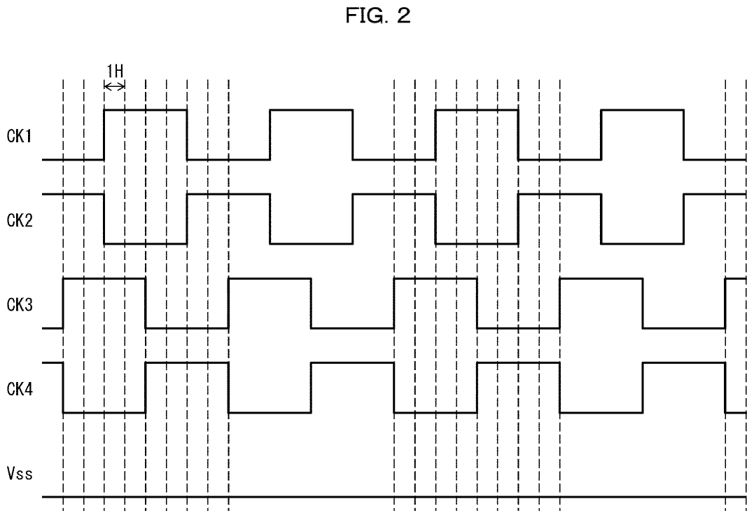

FIG. 2 is a signal view illustrating a schematic configuration of signal potential supplied by the low-potential trunk wire 34 and the clock trunk wires 35 to 38 illustrated in FIG. 1.

The low potential Vss is signal potential indicating “0” and is substantially fixed potential.

The clock signals CK1 to CK4 are the same in a length of one cycle and have the signal potential Vss indicating “0” and signal potential Vdd indicating “1” inverted every half cycle. When a length of one cycle of the clock signals CK1 to CK4 is 8H, a length of H is several μ seconds (for example, 8μ seconds).

The second clock signal CK2 is a signal whose cycle is earlier than that of the first clock signal CK1 by a half cycle. The third clock signal CK3 is a signal whose cycle is earlier than that of the first clock signal CK1 by a quarter cycle. The fourth clock signal CK4 is a signal whose cycle is earlier than that of the third clock signal CK3 by a half cycle (that is, a signal whose cycle is later than that of the first clock signal by a quarter cycle).

Though not illustrated in FIG. 2, the initialization signal Reset has the signal potential Vdd indicating “1” in a case where the scanning line drive circuit 47 is initialized, and has the signal potential indicating “0” in the other cases.

### (Circuit Configuration of Unit Circuit)

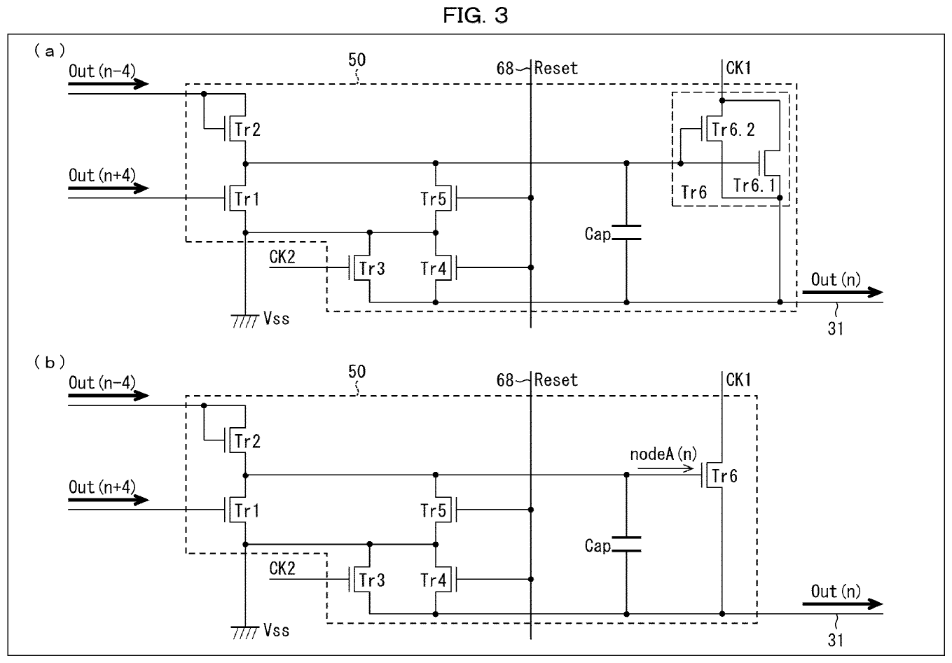

FIG. 3 is a circuit diagram illustrating a schematic circuit configuration of the unit circuit 50 on the nth stage illustrated in FIG. 1, in which n satisfies two conditions that (i) n is larger than 4 and smaller than N−3 and (ii) a remainder after n is divided by 8 is 1 or 2.

In the aforementioned two conditions, (i) is a condition to exclude a start stage (n=1, 2, 3, 4) where sequential driving of the scanning line 31 starts and an end stage (n=N−3, N−2, N−1, N) where the driving ends. Further, (ii) is a condition to specify the clock signals CK1 to CK4 input to the unit circuit 50.

For simplification of the description, the unit circuit 50 on the nth stage that satisfies the aforementioned two conditions will be described in the present chapter. A unit circuit 50 on the nth stage that does not satisfy the aforementioned two conditions has the same configuration as the circuit configuration of the unit circuit 50 illustrated in FIG. 3 except that a signal that is input varies in accordance with n.

As illustrated in FIG. 3(a), the unit circuit 50 on the nth stage includes a first transistor Tr1 (a circuit element group, a transistor group, a circuit element), a second transistor Tr2, a third transistor Tr3, a fourth transistor Tr4, a fifth transistor Tr5, a sixth transistor Tr6, and a bootstrap capacitor Cap. Hereinafter, the first transistor Tr1, the second transistor Tr2, the third transistor Tr3, the fourth transistor Tr4, the fifth transistor Tr5, and the sixth transistor Tr6 are collectively referred to as “transistors Tr1 to Tr6”.

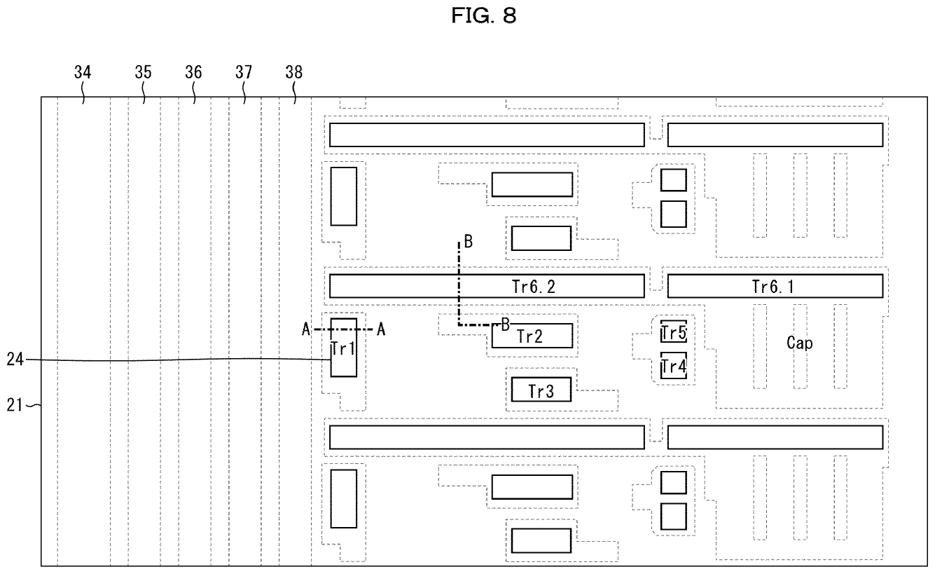

The sixth transistor Tr6 is a transistor group constituted by two transistors Tr6.1 and Tr6.2 that are connected in parallel. The two transistors Tr6.1 and Tr6.2 are separated by a semiconductor layer 24 (refer to FIG. 8) which serves as a channel thereof. The two transistors Tr6.1 and Tr6.2 have gate electrodes connected to each other, drain electrodes connected to each other, and source electrodes connected to each other, and thus function as one transistor. Therefore, the two transistors Tr6.1 and Tr6.2 are collectively treated as one sixth transistor Tr6. Accordingly, the circuit configuration illustrated in FIG. 3(a) is equivalent to the circuit configuration illustrated in FIG. 3(b).

The electrodes of the two transistors Tr6.1 and Tr6.2 that constitute the sixth transistor Tr6 are bonded to each other. In Embodiment 1, only the sixth transistor Tr6 is constituted by a plurality of transistors, but there is no limitation thereto. Each of the other transistors Tr1 to Tr5 is a transistor group constituted by one (single) transistor, but may be a transistor group constituted by a plurality of transistors. The bootstrap capacitor Cap is also able to be constituted by a plurality of capacitors.

The transistors Tr1 to Tr6 are (i) in a conductive state between a source and a drain while gate potential is equal to or more than the potential Vdd indicating “1” and (ii) in a non-conductive state between the source and the drain while the gate potential is the potential Vss indicating “0”. The transistors Tr1 to Tr6 are thin film transistors (TFTs) of a bottom-gate type and a channel-etched type that are formed on the insulating substrate 21, but are not limited thereto. The transistors Tr1 to Tr6 may be thin film transistors of another type such as a top-gate type or an etch-stop type. The scanning line drive circuit 47 may be arranged on a semiconductor substrate and the transistors Tr1 to Tr6 may be transistors of another type such as metal oxide semiconductor (MOS) transistors. Similarly, the bootstrap capacitor Cap may be any capacitor.

To a gate electrode of the first transistor Tr1, an output OUT(n+4) of a unit circuit 50 on a subsequent stage is input.

To a source electrode of the first transistor Tr1, a source electrode of the third transistor Tr3, a source electrode of the fourth transistor Tr4, and a source electrode of the fifth transistor Tr5, the low potential Vss is supplied.

A drain electrode of the first transistor Tr1, a drain electrode of the second transistor Tr2, a drain electrode of the fifth transistor Tr5, one electrode of the bootstrap capacitor Cap, and a gate electrode of the sixth transistor Tr6 are connected to each other. Potential of the gate electrode of the sixth transistor Tr6 is defined as nodeA(n).

To a gate electrode and a source electrode of the second transistor Tr2, an output Out(n−4) of a unit circuit 50 on a previous stage is input.

To a gate electrode of the third transistor Tr3, the second clock signal CK2 is input.

A drain electrode of the third transistor Tr3, a drain electrode of the fourth transistor Tr4, the other electrode of the bootstrap capacitor Cap, a drain electrode of the sixth transistor Tr6, and the scanning line 31 are connected to each other. Further, potential of the electrodes is output as Out(n) to the scanning line 31 and the unit circuits 50 on the subsequent stage and the previous stage.

To a source electrode of the sixth transistor Tr6, the first clock signal CK1 is input. The scanning line 31 reaches the signal potential Vdd through the sixth transistor Tr6 (i) while the nodeA(n) has the signal potential Vdd indicating “1” through the second transistor Tr2 by the output Out(n−4), and further, (ii) when the first clock signal CK1 reaches the signal potential Vdd. Further, as the first clock signal CK1 is inverted from “0” to “1” and the scanning line 31 is charged to the signal potential Vdd, the potential of the gate electrode of the sixth transistor Tr6 and the potential of the one electrode of the bootstrap capacitor rise. Thus, the nodeA(n) has signal potential indicating “1+α” which is higher than the signal potential Vdd (α>0). Note that, α is responsive to a total capacity of capacity between the electrodes of the bootstrap capacitor Cap and capacity between the gate electrode and the train electrode of the sixth transistor Tr6.

After that, when the second clock signal CK2 is inverted from “0” to “1”, the scanning line 31 is returned to an initial state of the signal potential Vss through the third transistor Tr3. Further, when the output Out(n+4) of the unit circuit 50 on the subsequent stage reaches the signal potential Vdd indicating “1”, the nodeA(n) is returned to the initial state of Vss through the first transistor Tr1.

The sixth transistor Tr6 outputs drain potential to the scanning line 31 and is thus an output transistor (output transistor group) of the unit circuit 50. Therefore, in order to achieve sufficiently high capability of being charged to the scanning line 31, the sixth transistor Tr6 preferably has low channel resistance when being in the conductive state between the source and the drain and has large source-drain current that is able to flow in the conductive state. Accordingly, the sixth transistor Tr6 preferably has a wide channel width and a short channel length. Thus, the sixth transistor Tr6 easily occupies a wider area on the insulating substrate 21 in plan view than those of the other transistors Tr1 to Tr5.

The bootstrap capacitor Cap is a capacitor that keeps a potential difference between the gate and the drain of the sixth transistor Tr6 and raises the potential of the nodeA(n) to higher potential so that Out(n) reaches the potential Vdd during an output period thereof, and thus preferably has sufficiently large capacity. Therefore, the bootstrap capacitor Cap also easily occupies a wider area on the insulating substrate 21 in plan view than those of the transistors Tr1 to Tr5 other than the sixth transistor Tr6.

With such a circuit configuration, the output Out(n) of the unit circuit 50 on the nth stage is obtained as indicated by a table 1.

TABLE 1

| Input | | | | | | Output |
|---|---|---|---|---|---|---|
| Reset | CK1 | CK2 | Out (n − 4) | Out (n + 4) | nodeA (n) | Out (n) |
| 0 | 0 | 1 | 1 | 0 | 1 | 0 |
| 0 | 1 | 0 | 0 | 0 | 1 + α | 1 |
| 0 | 0 | 1 | 0 | 1 | 0 | 0 |
| 0 | 1 | 0 | 0 | 0 | 0 | 0 |
| 0 | 0 | 1 | 0 | 0 | 0 | 0 |

* α > 0

Until sequential driving of the scanning line 31 starts from the start stage and ends at the end stage, the initialization signal Reset=0 is provided, but immediately after the driving ends at the end stage or before the driving starts again from the start stage, the initialization signal Reset=1 is provided and the nodeA(n) of each stage is returned to the initial state of Vss. Similarly, the scanning line 31 is also returned to the initial state of the low potential Vss. Then, immediately before the driving starts from the start stage, the initialization signal Reset=0 is provided again. By regularly and simultaneously returning the nodeA(n) of each stage and the scanning line 31 to the initial state by using the initialization signal, an erroneous operation of the scanning line drive circuit 47 in a long-time operation is able to be suppressed.

Note that, the unit circuit 50 illustrated in FIG. 3 is an example and does not limit the scope of the invention. The unit circuit 50 may be a flip-flop circuit having another circuit configuration or a circuit other than a flip-flop circuit. Further, the scanning line drive circuit 47 may include unit circuits 50 of a plurality of types that have different circuit configurations.

### (Circuit Arrangement of Drive Circuit)

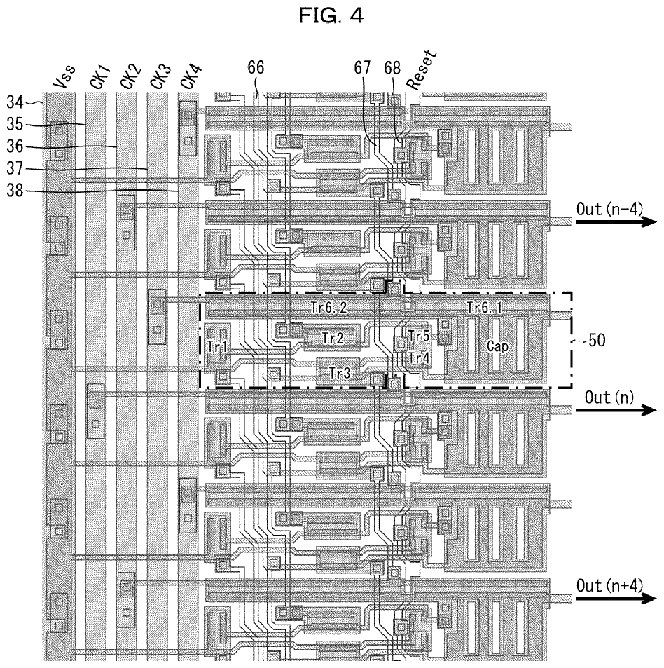

FIG. 4 is a plan view schematically illustrating circuit arrangement of the scanning line drive circuit 47 illustrated in FIG. 1.

As illustrated in FIG. 4, the scanning line drive circuit 47 further includes a first relay wire 66 (first-type wire), a second relay wire 67 (first-type wire), and the initialization wire 68 (first-type wire) that connect the unit circuits 50. In Embodiment 1, the initialization wire 68 passes through the inner side of the scanning line drive circuit 47 and is connected to the plurality of unit circuits 50. Thus, the initialization wire 68 is a wire that supplies the initialization signal Reset to the scanning line drive circuit 47 and is also a wire that connects the unit circuits 50.

The first relay wire 66 is a relay wire that supplies the output Out(n) of the unit circuit 50 on the nth stage to a gate electrode of a first transistor of a unit circuit 50 on an (n−4)th stage and a gate electrode of a second transistor of a unit circuit 50 on an (n+4)th stage. Thus, the first relay wire 66 that supplies the output Out(n) extends over five unit circuits 50 on the (n−4)th stage, an (n−2)th stage, the nth stage, an (n+2)th stage, and the (n+4)th stage. Moreover, the first relay wire 66 that supplies the output Out(n) connects (i) the unit circuits 50 on the (n−4)th stage and the nth stage and connects (ii) the unit circuits 50 on the nth stage and the (n+4)th stage.

The second relay wire 67 is a relay wire that extends from (i) the source electrode of the transistor Tr6.2 constituting the sixth transistor Tr6 of the unit circuit 50 on the nth stage, to the source electrode of which any of the clock signals CK1 to CK4 is supplied, to (ii) a gate electrode of the third transistor Tr3 of the unit circuit 50 on the (n−4)th stage. The second relay wire 67 is also a relay wire that supplies any of the clock signals CK1 to CK4. Thus, the second relay wire 67 that supplies any of the clock signals CK1 to CK4 from the unit circuit 50 on the nth stage extends over three unit circuits 50 on the (n−4)th stage, the (n−2)th stage, and the nth stage. The second relay wire 67 that supplies any of the clock signals CK1 to CK4 from a branch wire of the unit circuit 50 on the nth stage connects the unit circuits 50 on the (n−4)th stage and the nth stage.

The initialization wire 68 supplies the initialization signal Reset directly to gate electrodes of fourth transistors Tr4 and fifth transistors Tr5 of the respective unit circuits 50. Thus, the initialization wire 68 extends over all unit circuits 50 on odd-numbered stages and over all unit circuits 50 on even-numbered stages. Further, the initialization wire 68 connects (i) the unit circuits 50 on the (n−2)th stage and the nth stage and connects (ii) the unit circuits 50 on the nth stage and the (n+2)th stage.

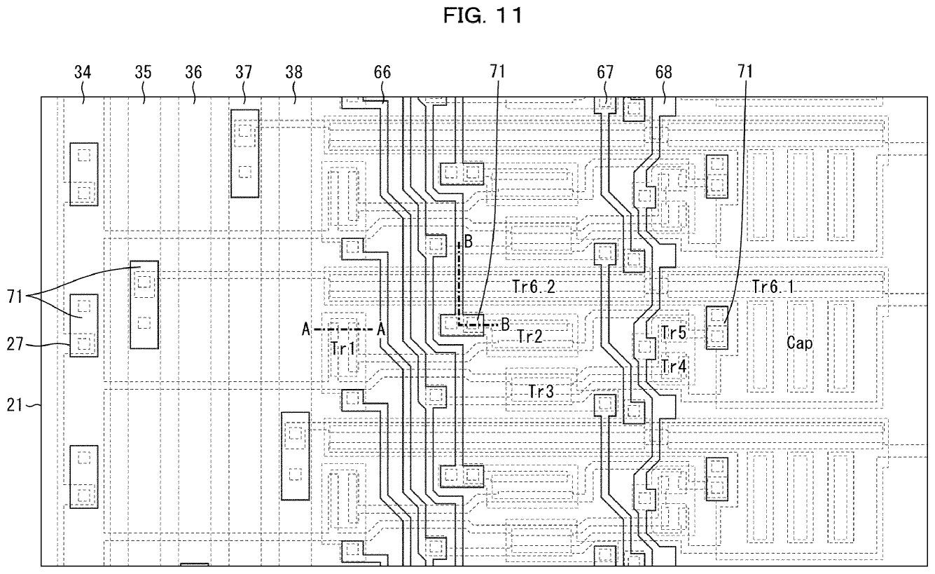

The first relay wire 66, the second relay wire 67, and the initialization wire 68 are wires that extend substantially in parallel to the data lines 32 and are wires formed by an additional wire layer 27 (refer to FIG. 11) as described below.

### (Circuit Arrangement of Unit Circuit)

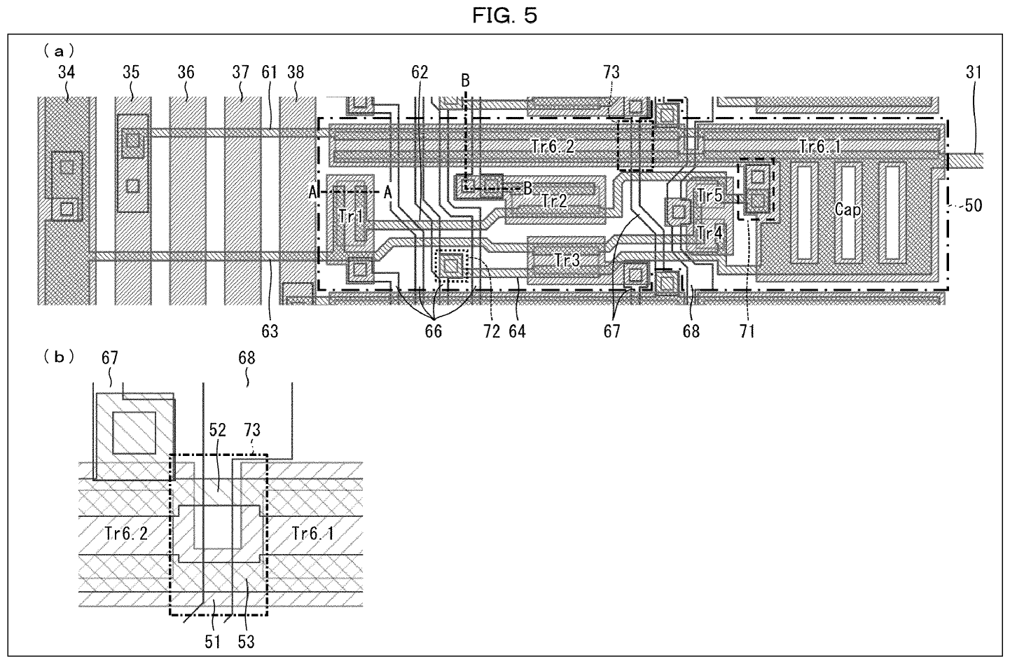

FIG. 5 is a plan view schematically illustrating circuit arrangement of the unit circuit 50 illustrated in FIG. 4. FIG. 5(a) schematically illustrates circuit arrangement of the unit circuit on the nth stage, in which n satisfies two conditions that (i) n is larger than 4 and smaller than N−3 and (ii) a remainder after n is divided by 8 is 1 or 2, similarly to FIG. 3. FIG. 5(b) is an enlarged view of an overlapping portion 73 in which the initialization wire 68 crosses the sixth transistor Tr6 and a vicinity thereof.

For simplification of the description, the unit circuit 50 on the nth stage that satisfies the aforementioned two conditions will be described in the present chapter. A unit circuit 50 on the nth stage that does not satisfy the aforementioned two conditions is arranged in the same manner as in the circuit arrangement of the unit circuit 50 illustrated in FIG. 5 except that a trunk wire to be connected among the clock trunk wires 35 to 38 and/or a connection destination of the first relay wire 66 and/or the second relay wire 67 vary in accordance with n.

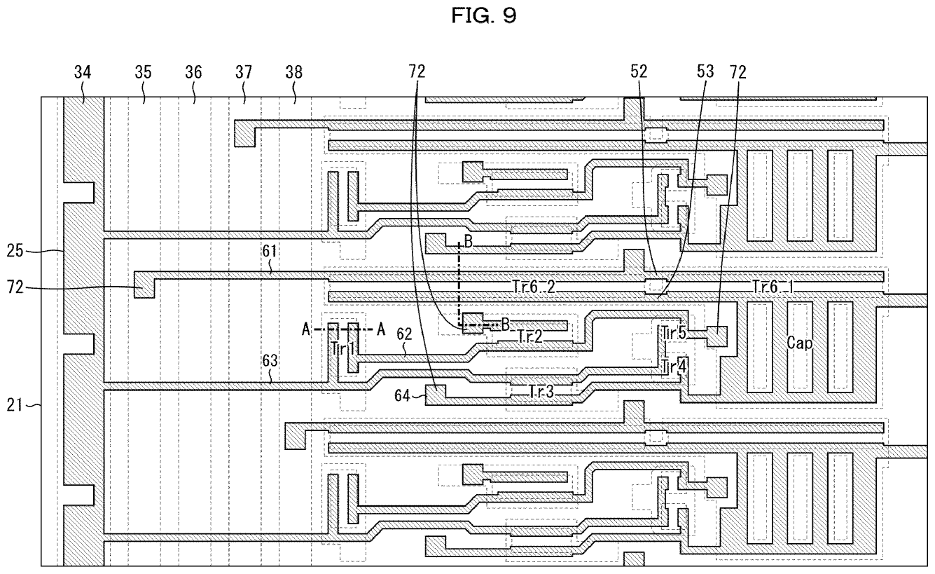

As illustrated in FIG. 5(a), the unit circuit 50 on the nth stage further includes a first branch wire 61, a second branch wire 62, a third branch wire 63, a fourth branch wire 64, and a reconnection portion 71. Hereinafter, the first branch wire 61, the second branch wire 62, the third branch wire 63, and the fourth branch wire 64 are collectively referred to as “branch wires 61 to 64”. Further, the branch wires 61 to 64 are wires formed by a source layer 25 (refer to FIG. 9) as described below.

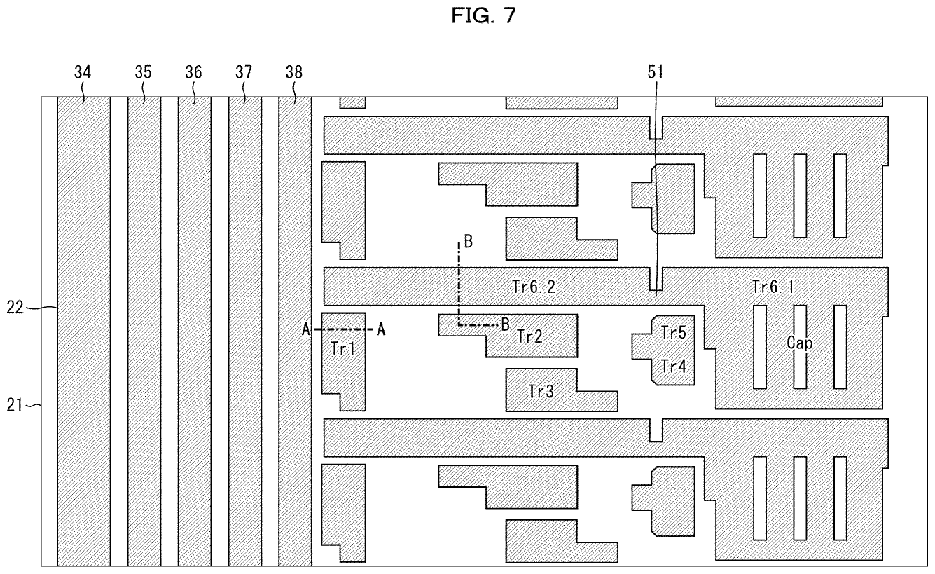

The reconnection portion 71 is a short-distance wire by which the branch wires 61 to 64 formed by the source layer 25 (refer to FIG. 9) are reconnected to the wires (the low-potential trunk wire 34, the clock trunk wires 35 to 38, the first relay wire 66, and the second relay wire 67) formed by the gate layer 22 (refer to FIG. 7) or the electrodes (the gate electrode of the second transistor Tr2, and the one electrode of the bootstrap capacitor Cap, which is integrated with the gate electrode of the sixth transistor Tr6).

The first branch wire 61 is a branch wire by which the source electrode of the transistor T6.2 constituting the sixth transistor Tr6 is connected to the first clock trunk wire 35. The first branch wire 61 is a branch wire that supplies the first clock signal CK1. The first branch wire 61 includes, at a left end of FIG. 5, a connection portion 72 that allows connection to the first clock trunk wire 35 through the reconnection portion 71. The first branch wire 61 is formed to be integrated with the source electrode of the transistor Tr6.2.

The second branch wire 62 is a branch wire by which the one electrode of the bootstrap capacitor Cap, which is integrated with the gate electrode of the sixth transistor Tr6, is connected to the drain electrodes of the first transistor Tr1, the second transistor Tr2, and the fifth transistor Tr5. The second branch wire includes, at a right end of FIG. 5, a connection portion 72 that allows connection to the one electrode of the bootstrap capacitor Cap through the reconnection portion 71. The second branch wire 62 is formed to be integrated with the drain electrodes of the first transistor Tr1, the second transistor Tr2, and the fifth transistor Tr5.

The third branch wire 63 is a branch wire by which the low-potential trunk wire 34 is connected to the source electrodes of the first transistor Tr1, the third transistor Tr3, the fourth transistor Tr4, and the fifth transistor Tr5. The third branch wire 63 is a branch wire that supplies the low potential Vss. The third branch wire 63 includes, at the left end of FIG. 5, a connection portion 72 that allows connection to the low-potential trunk wire 34 through the reconnection portion 71. The third branch wire 63 is formed to be integrated with the source electrodes of the first transistor Tr1, the third transistor Tr3, the fourth transistor Tr4, and the fifth transistor Tr5.

The fourth branch wire 64 is a branch wire by which the first relay wire 66, the drain electrode of the third transistor Tr3, the drain electrode of the fourth transistor Tr4, and the other electrode of the bootstrap capacitor Cap, which is integrated with the drain electrode of the transistor Tr6.1 constituting the sixth transistor Tr6, are connected. The fourth branch wire 64 is a branch wire that supplies the output Out(n) of the unit circuit 50 on the nth stage. The fourth branch wire 64 includes, at the left end of FIG. 5, a connection portion 72 that allows connection to the first relay wire 66 through the reconnection portion 71. The fourth branch wire 64 is formed to be integrated with the drain electrodes of the third transistor and the fourth transistor, and the other electrode of the bootstrap capacitor Cap.

The first relay wire 66, the second relay wire 67, and the initialization wire 68 cross the sixth transistor Tr6 at the overlapping portion 73.

As illustrated in FIG. 5(b), the sixth transistor Tr6 is divided into the two transistors Tr6.1 and Tr6.2 by the overlapping portion 73 with the initialization wire 68. The sixth transistor Tr6 further includes a bonding wire 51 (second-type wire) by which the gate electrodes of the two transistors Tr6.1 and Tr6.2 are bonded, a bonding wire 52 (second-type wire) by which the source electrodes of the two transistors Tr6.1 and Tr6.2 are bonded, and a bonding wire 53 (second-type wire) by which the drain electrodes of the two transistors Tr6.1 and Tr6.2 are bonded.

The bonding wire 51 between the gate electrodes is preferably thinner than the gate electrodes of the two transistors Tr6.1 and Tr6.2. The bonding wire 52 between the source electrodes is preferably thinner than the source electrodes of the two transistors Tr6.1 and Tr6.2. The bonding wire 53 between the drain electrodes is preferably thinner than the drain electrodes of the two transistors Tr6.1 and Tr6.2. The semiconductor layer 24 (refer to FIG. 8) that forms the channel of the sixth transistor Tr6 is preferably not on an inner side of the overlapping portion 73. This is because this makes it possible to reduce interaction between the sixth transistor Tr6 and the initialization wire 68 at the overlapping portion 73.

Since such reduction of the interaction makes it possible to reduce wiring capacity of the initialization wire 68, a signal rounding of the initialization signal Reset supplied by the initialization wire 68 is able to be reduced. The initialization wire 68 extends over all unit circuits 50 included in one scanning line drive circuit 47, so that the reduction of the signal rounding is particularly advantageous in the initialization wire 68. Further, such reduction of the interaction is able to reduce an erroneous operation of the unit circuit 50 caused by a back gate effect by which the initialization wire 68 functions as a back gate of the sixth transistor Tr6.

### (Layered Structure of Transistor)

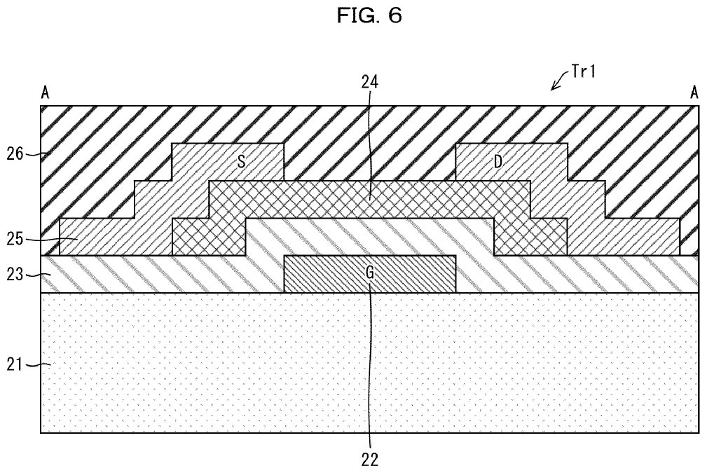

FIG. 6 is a sectional view taken along a line A-A of FIG. 5 and a sectional view illustrating a schematic layered structure of the first transistor Tr1. Though description will be omitted, the transistors Tr2 to Tr6 other than the first transistor Tr1 also have a similar layered structure.

The first transistor Tr1 according to Embodiment 1 is a TFT of the bottom-gate type and the channel-etched type. Thus, the first transistor is formed on the insulating substrate 21 and includes a gate electrode (G) formed by the gate layer 22 (second conductive layer), a gate insulating film 23, a channel formed by the semiconductor layer 24, a source electrode (S) and a drain electrode (D) formed by the source layer 25 (third conductive layer), and a first interlayer insulating film 26.

The insulating substrate 21 is a substrate that supports the scanning line drive circuit 47. The insulating substrate 21 may be formed by any material as long as being a material having an insulating property, and a glass substrate or a plastic substrate made from polyethylene terephthalate, polyimide, or the like may be used, for example.

The gate layer 22 is a conductive layer formed on the insulating substrate 21. The gate layer 22 is able to be formed by a metal material, for example, such as titanium (Ti), copper (Cu), chromium (Cr), aluminum (Al), gold (Au), molybdenum (Mo), tungsten (W), or an alloy thereof.

The gate insulating film 23 is an insulating film formed so as to cover surfaces of the insulating substrate 21 and the gate layer 22. The gate insulating film 23 may be formed, for example, by an organic insulating material such as polyparavinylphenol (PVP) or an inorganic insulating material such as silicon dioxide (SiO₂) or silicon nitride (SiNₓ).

The semiconductor layer 24 is a semiconductor layer that is formed on the gate insulating film 23 and makes the source electrode (S) and the drain electrode (D) conductive. The semiconductor layer 24 may be constituted by, for example, an oxide semiconductor.

The oxide semiconductor constituting the semiconductor layer 24 may be an amorphous oxide semiconductor or a crystalline oxide semiconductor having a crystalline part. A polycrystalline oxide semiconductor, a microcrystalline oxide semiconductor, or a crystalline oxide semiconductor in which a c-axis is oriented substantially perpendicular to a layer surface, or the like is cited as the crystalline oxide semiconductor.

The semiconductor layer 24 constituted by the oxide semiconductor may have a layered structure of two or more layers. In a case where the semiconductor layer 24 has a layered structure, the semiconductor layer 24 may include an amorphous oxide semiconductor layer and a crystalline oxide semiconductor layer. The semiconductor layer 24 may include a plurality of crystalline oxide semiconductor layers having different crystal structures. In addition, the semiconductor layer 24 may include a plurality of amorphous oxide semiconductor layers.

In a case where the semiconductor layer 24 has a two-layer structure including an upper layer (opposite to the substrate) and a lower layer (substrate side), an energy gap of the oxide semiconductor included in the upper layer is preferably greater than an energy gap of the oxide semiconductor included in the lower layer. In a case where a difference in the energy gap between the layers is relatively small, however, the energy gap of the oxide semiconductor in the lower layer may be greater than the energy gap of the oxide semiconductor in the upper layer.

For example, Japanese Unexamined Patent Application Publication No. 2014-007399 describes a material, a structure, and a film formation method of the amorphous oxide semiconductor and each of the aforementioned crystalline oxide semiconductors, a configuration of an oxide semiconductor layer having a layered structure, and the like. The entire contents disclosed in Japanese Unexamined Patent Application Publication No. 2014-007399 are incorporated into the present specification by reference.

The semiconductor layer 24 may contain at least one kind of metal element among In, Ga, and Zn, for example. In the present embodiment, the semiconductor layer 24 contains, for example, an In—Ga—Zn—O semiconductor (for example, indium gallium zinc oxide). Here, the In—Ga—Zn—O semiconductor is a ternary oxide of In (indium), Ga (gallium), and Zn (zinc), and a ratio (composition ratio) of In, Ga, and Zn is not particularly limited and includes, for example, In:Ga:Zn=2:2:1, In:Ga:Zn=1:1:1, In:Ga:Zn=1:1:2, or the like. Such an oxide semiconductor layer is able to be formed from an oxide semiconductor layer containing an In—Ga—Zn—O semiconductor.

The In—Ga—Zn—O semiconductor may be amorphous or crystalline. For a crystalline In—Ga—Zn—O semiconductor, a crystalline In—Ga—Zn—O semiconductor in which a c-axis is oriented substantially perpendicular to a layer surface is preferable.

Note that, for example, Japanese Unexamined Patent Application Publications No. 2014-007399 described above, No. 2012-134475, No. 2014-209727, and the like disclose crystal structures of crystalline In—Ga—Zn—O semiconductors. The entire contents disclosed in Japanese Unexamined Patent Application Publications No. 2012-134475 and No. 2014-209727 are incorporated into the present specification by reference.

A thin film transistor having an In—Ga—Zn—O semiconductor layer has a high mobility (greater than 20 times that of an a-Si TFT) and a low leak current (less than 1/100th that of the a-Si TFT), and is thus suitably used as the transistors Tr1 to Tr6 provided in the scanning line drive circuit 47 and the pixel transistor arranged in the display region 30.

The semiconductor layer 24 may contain another oxide semiconductor instead of an In—Ga—Zn—O semiconductor. For example, the semiconductor layer 24 may contain an In—Sn—Zn—O semiconductor (for example, In₂O₃—SnO₂—ZnO; InSnZnO). The In—Sn—Zn—O semiconductor is a ternary oxide of In (indium), Sn (tin), and Zn (zinc). The oxide semiconductor layer may contain an In—Al—Zn—O semiconductor, an In—Al—Sn—Zn—O semiconductor, a Zn—O semiconductor, an In—Zn—O semiconductor, a Zn—Ti—O semiconductor, a Cd—Ge—O semiconductor, a Cd—Pb—O semiconductor, CdO (cadmium oxide), a Mg—Zn—O semiconductor, an In—Ga—Sn—O semiconductor, an In—Ga—O semiconductor, a Zr—In—Zn—O semiconductor, a Hf—In—Zn—O semiconductor, or the like.

The source layer 25 is able to be formed by a metal material, for example, such as titanium (Ti), copper (Cu), chromium (Cr), gold (Au), aluminum (Al), molybdenum (Mo), tungsten (W), or an alloy thereof.

The first interlayer insulating film 26 fills a space between the source electrode (S) and the drain electrode (G) which are formed by the source layer 25 so as to be separated from each other on the gate insulating film 23 and the semiconductor layer 24. The first interlayer insulating film 26 is provided on upper surfaces of the gate insulating film 23, the semiconductor layer 24, and the source layer 25. A material of the first interlayer insulting film 26 may be the same insulating material as that of the gate insulating film 23 or an insulating material different from that of the gate insulating film 23.

The layers (the gate layer 22, the gate insulating film 23, the semiconductor layer 24, the source layer 25, and the first interlayer insulating film 26) constituting the transistors Tr1 to Tr6 provided in the scanning line drive circuit 47 are preferably layers constituting the pixel transistor arranged in the display region 30.

### (Production Process of Scanning Line Drive Circuit)

A schematic process of producing the scanning line drive circuit 47 illustrated in FIG. 4 will be described below with reference to FIGS. 7 to 11. Note that, though description will be omitted, components of the data line drive circuit 48, and the pixel transistor and the pixel electrode in the display region 30 are also formed on the insulating substrate 21 with the scanning line drive circuit 47.

FIG. 7 is a plan view illustrating a schematic pattern of the gate layer 22 of the scanning line drive circuit 47 illustrated in FIG. 4.

FIG. 8 is a plan view illustrating a schematic pattern of the semiconductor layer 24 of the scanning line drive circuit 47 illustrated in FIG. 4.

FIG. 9 is a plan view illustrating a schematic pattern of the source layer 25 of the scanning line drive circuit 47 illustrated in FIG. 4.

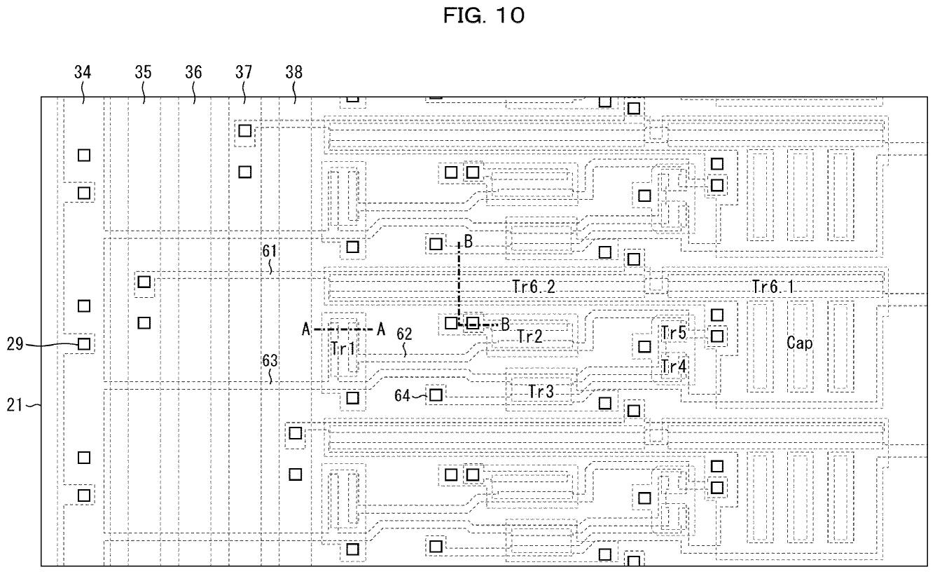

FIG. 10 is a plan view illustrating a schematic pattern of a contact hole 29 of the scanning line drive circuit 47 illustrated in FIG. 4.

FIG. 11 is a plan view illustrating a schematic pattern of the additional wire layer 27 of the scanning line drive circuit 47 illustrated in FIG. 4.

First, a conductive material is deposited entirely on the insulating substrate 21 to form the gate layer 22. After that, the gate layer 22 is subjected to etching by using a photolithography technique or the like so that the gate layer 22 remains with a pattern as in FIG. 7. Thereby, the low-potential trunk wire 34, the clock trunk wires 35 to 38, the gate electrodes of the transistors Tr1 to Tr6, the one electrode of the bootstrap capacitor Cap, the bonding wire 51 between the gate electrodes are formed as in FIG. 7.

Then, the gate insulating film 23 is entirely deposited on the insulating substrate 21 over the gate layer 22. The gate insulating film 23 is an insulating film that forms gate insulating films of the transistors Tr1 to Tr6 provided in the scanning line drive circuit 47. It is preferable that the gate insulating film 23 is also an insulating film that forms a gate insulating film of the pixel transistor arranged in the display region 30.

Next, a semiconductor material is entirely deposited on the insulating substrate 21 over the gate insulating film 23 to form the semiconductor layer 24. After that, the semiconductor layer 24 is subjected to etching by using the photolithography technique or the like so that the semiconductor layer 24 remains with a pattern as in FIG. 8. Thereby, the semiconductor layer 24 serving as a channel of the transistors Tr1 to Tr6 is formed as in FIG. 8.

Next, a conductive material is entirely deposited on the insulating substrate 21 over the semiconductor layer 24 to form the source layer 25. After that, the source layer 25 is subjected to etching by using the photolithography technique or the like so that the source layer 25 remains with a pattern as in FIG. 9. Thereby, the source electrodes and the drain electrodes of the transistors Tr1 to Tr6, the branch wires 61 to 64, the one electrode of the bootstrap capacitor Cap, the scanning line 31, the bonding wire 52 between the source electrodes, and the bonding wire 53 between the drain electrodes are formed as in FIG. 9. Note that, the scanning line 31 is formed in the gate layer 22 in the display region 30. The scanning line 31 that is formed to be integrated with the one electrode of the bootstrap capacitor Cap is formed by the source layer 25, but is reconnected to the gate layer 22 outside the display region 30 (inside the peripheral region 40).

As illustrated in FIG. 9, the connection portion 72 of the third branch wire 63, which allows connection to the low-potential trunk wire 34, is preferably arranged so that connection portions 72 of unit circuits 50 on a plurality of stages are continuous to be overlapped with the low-potential trunk wire 34. The connection portions 72 arranged in this manner function like another low-potential trunk wire 34, thus making it possible to reduce wiring resistance of the low-potential trunk wire 34.

Then, an insulating material is entirely deposited on the insulating substrate 21 over the source layer 25 to form the first interlayer insulating film 26.

Next, the contact hole 29 is formed as in FIG. 10 by using the photolithography technique or the like. At a position (the connection portions 72 of the branch wires 61 to 64) where the source layer 25 remains, the first interlayer insulating film 26 is subjected to etching to expose the source layer 25 from the contact hole 29. At a position where the source layer 25 is removed and the gate layer 22 remains, the first interlayer insulating film 26 and the gate insulating film 23 are subjected to etching to expose the gate layer 22 from the contact hole 29.

Next, a conductive material is entirely deposited on the insulating substrate 21 over the first interlayer insulating film 26 to form the additional wire layer 27 (first conductive layer). After that, the additional wire layer 27 is subjected to etching by using the photolithography technique or the like so that the additional wire layer 27 remains with a pattern as in FIG. 11. Thereby, the reconnection portion 71, the first relay wire 66, the second relay wire 67, and the initialization wire 68 are formed and the conductive material forming the additional wire layer 27 is buried in the contact hole 29. Thus, the additional wire layer 27 is connected to the gate layer 22 through the contact hole 29 from which the gate layer 22 is exposed. Further, the additional wire layer 27 is connected to the source layer 25 through the contact hole 29 from which the source layer 25 is exposed.

A metal material, for example, such as copper (Cu), titanium (Ti), aluminum (Al), or an alloy thereof is usable for the additional wire layer 27. The additional wire layer 27 may be a wire that reduces resistance of a common electrode which is arranged in a display region and forms auxiliary capacitance in a TN (twisted nematic) system or a common electrode in an FFS (fringe field switching) system, or may be a conductive layer for a channel light shielding film of a TFT. It is preferable that the additional wire layer 27 is such an existing conductive layer, because the number of wire layers is not increased.

Then, an insulating material is entirely deposited on the insulating substrate 21 over the source layer 25 to form a second interlayer insulating film 28. A material of the second interlayer insulating film 28 may be the same insulating material as that of the first interlayer insulating film 26 or may be an insulating material different from that of the first interlayer insulating film 26. For example, the second interlayer insulating film 28 may be silicon nitride (SiNₓ) having a thickness of 0.2 mm to 0.8 mm.

### (Partial Sectional Surface of Scanning Line Drive Circuit)

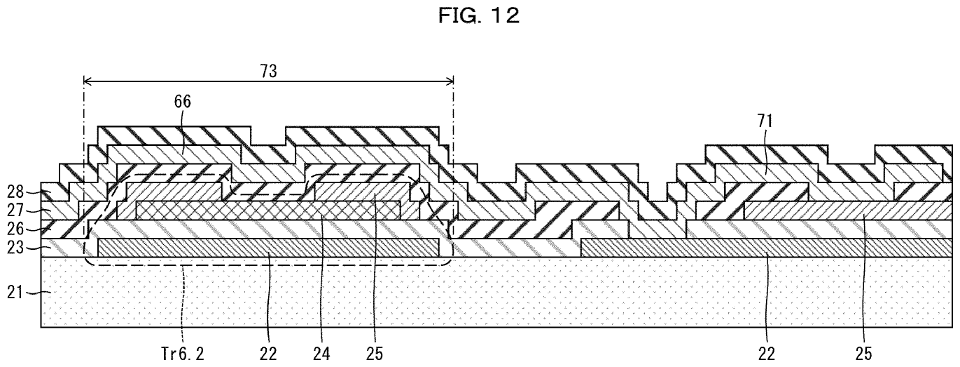

FIG. 12 is a sectional view taken along a line B-B of FIG. 5 and a sectional view illustrating a schematic configuration of the overlapping portion 73 and the reconnection portion 71. The overlapping portion 73 illustrated in FIG. 12 is a crossing portion where the transistor Tr6.2 included in the sixth transistor Tr6 crosses the first relay wire 66. Further, the reconnection portion 71 illustrated in FIG. 12 is formed to be integrated with the first relay wire 66 and connects the gate electrode of the second transistor Tr2 to the source electrode.

As illustrated in FIG. 12, in the overlapping portion 73, the first relay wire 66 formed by the additional wire layer 27 crosses the transistor Tr6.2. In the configuration illustrated in FIG. 12, the first relay wire 66 is not held between the source electrode, the drain electrode, and the gate electrode of the transistor Tr6.2. Thus, compared to a configuration in which the first relay wire 66 is held therebetween, interaction between the first relay wire 66 and the transistor Tr6.2 is small, thus making it possible to reduce a signal rounding and an erroneous operation.

Accordingly, layering the gate layer 22, the source layer 25, and the additional wire layer 27 on the insulating substrate 21 in this order as in FIG. 12 reduces interaction between the sixth transistor Tr6 and the first relay wire 66, the second relay wire 67, or the initialization wire 68 in the overlapping portion 73, and is thus preferable.

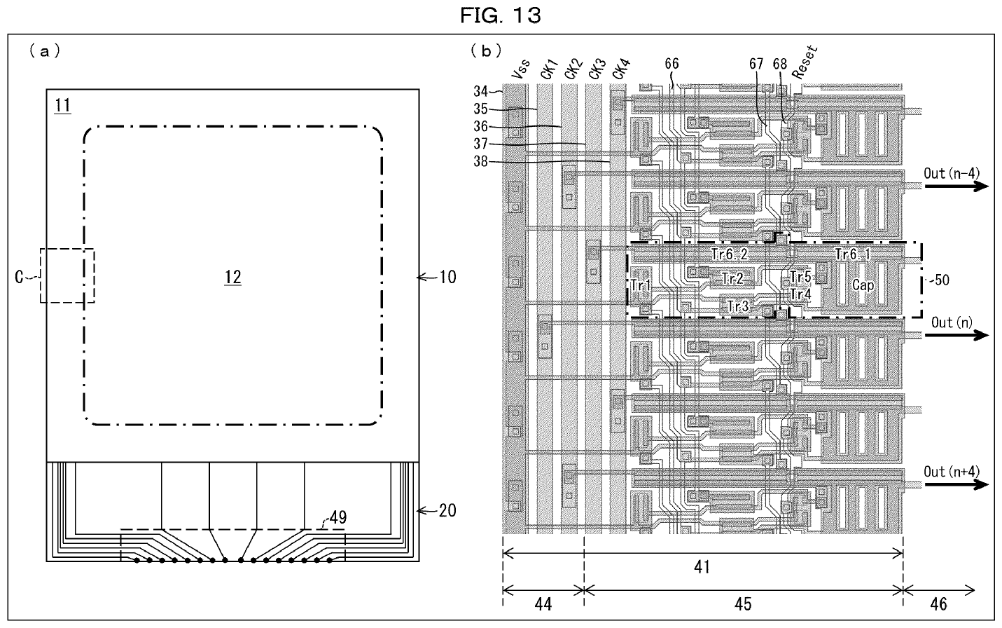

As illustrated in FIG. 12, in a region where the scanning line drive circuit 47 is formed, a top layer of the layered structure that is layered on the insulating substrate 21 is the second interlayer insulating film 28. In this manner, it is preferable that the top layer is the insulating film because this makes it easy to form a seal 11 (refer to FIG. 13) on the scanning line drive circuit 47. In a configuration in which the top layer is a conductive layer, the conductive layer is easily broken by a spacer included in a seal material. Moreover, in a case where a liquid crystal display device of a TN (twisted nematic) system or a VA (vertical aligned) system uses a spacer in which conductive particles are mixed to achieve conductivity with a counter electrode provided on a counter substrate, short-circuit is easily caused by the conductive particles. On the other hand, in the configuration in which the top layer is the insulating film, breakage or short-circuit of the conductive layer is hardly caused.

For a similar reason, it is also preferable that a top layer of the layered structure that is layered on the insulating substrate 21 is an insulating film in the peripheral region 40. Note that, since the seal 11 is not formed in the display region 30, the top layer of the display region 30 may be a transparent conductive layer in which a pixel electrode is formed, or the like.

### (Display Panel)

FIG. 13 is a plan view illustrating a schematic configuration of a liquid crystal display panel 100 (display device) using the matrix substrate 20 illustrated in FIG. 1. FIG. 13(a) is a perspective plan view of the liquid crystal display panel 100. FIG. 13(b) is an enlarged view of a surrounded part C of FIG. 13(a) in the matrix substrate 20.

As illustrated in FIG. 13(a), the liquid crystal display panel 100 includes the matrix substrate 20, a counter substrate 10 facing the matrix substrate, liquid crystal 12 (electrooptical substance) enclosed between the counter substrate 10 and the matrix substrate 20, and the seal 11 by which the liquid crystal 12 is enclosed.

The seal 11 is formed in a seal region 41, which is included in the peripheral region 40, so as to extend along an outer peripheral of the counter substrate 10 and enable the terminal portion 49 of the matrix substrate 20 to be connected to outside. As the seal material forming the seal 11, photosetting resin is normally used. Thus, in the seal region 41 where the seal 11 is formed, a light transmission portion through which light that cures the seal material is able to be transmitted is provided in the matrix substrate 20. Further, a spacer that keeps an interval between the counter substrate 10 and the matrix substrate 20 is normally mixed in the seal material.

As illustrated in FIG. 13(b), the seal region 41 is overlapped with (i) a trunk wire region 44 where the low-potential trunk wire 34 and the clock trunk wires 35 to 38 are arranged and (ii) a drive circuit region 45 where the scanning line drive circuit 47 is arranged. Compared to a configuration in which the seal region 41 is not overlapped with the trunk wire region 44 or the drive circuit region 45, such an overlapping configuration makes it possible to reduce an area of the peripheral region 40, and is thus preferable. Further, a rate with which the seal region 41 is overlapped with the drive circuit region 45 is preferably high to reduce the area of the peripheral region 40. Accordingly, a configuration in which the seal region 41 is completely overlapped with the trunk wire region 44 and the drive circuit region 45 as in FIG. 13(b) is more preferable.

### (Comparison)

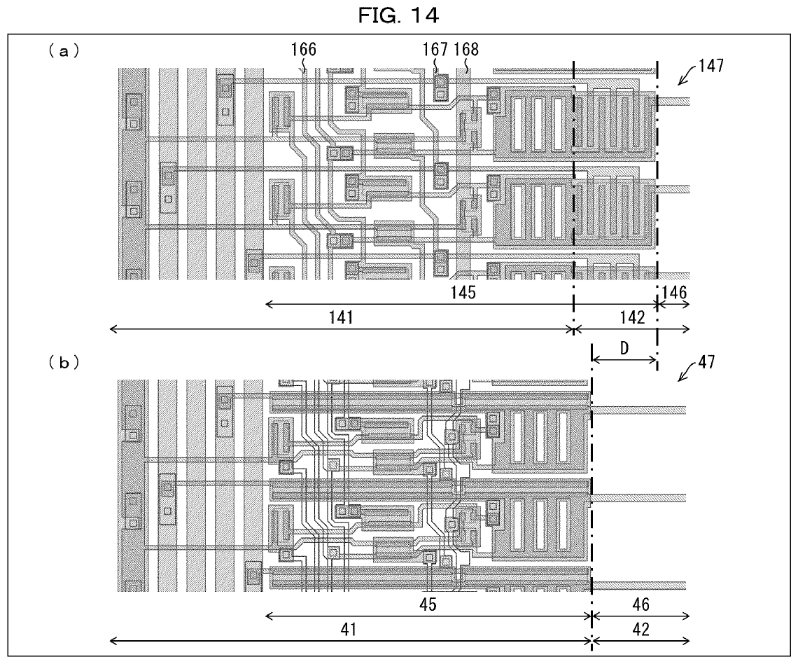

FIG. 14 is a view in which (a) a scanning line drive circuit 147 of a comparative example and (b) the scanning line drive circuit 47 according to Embodiment 1 of the invention are compared.

The scanning line drive circuit 147 of the comparative example has a configuration including neither the additional wire layer 27 nor the second interlayer insulating film 28. Thus, in the conventional scanning line drive circuit 147, a first relay wire 166, a second relay wire 167, and an initialization wire 168 are formed by the gate layer 22. Accordingly, the scanning line drive circuit 147 of the comparative example and the scanning line drive circuit 47 according to Embodiment 1 of the invention are different in circuit arrangement, but are the same in a circuit configuration.

As illustrated in FIG. 14(a), in the comparative example, the scanning line drive circuit 147 is arranged so that the sixth transistor Tr6 which is an output transistor is on an outer side of a seal region 141. This is because the output transistor has a wide channel width and a short channel length so as to have sufficiently high capability of being charged to the scanning line 31.

It is assumed that the output transistor has a long and narrow shape formed so as to be short in an extension direction of the data line 32 and long in an extension direction of the scanning line 31. In such a case, the output transistor is able to have a wide channel width. However, the first relay wire 166, the second relay wire 167, and the initialization wire 168 in the comparative example are formed by the gate layer 22, and thus need to circumvent the sixth transistor Tr6. Thus, a width of a drive circuit region 145, in which the scanning line drive circuit 147 is arranged, in the extension direction of the scanning line 31 becomes wide, so that a rate with which the drive circuit region 145 is overlapped with the seal region 141 is rather reduced. Further, circuit arrangement of the scanning line drive circuit 147 easily becomes inefficient, so that the comparative example is not preferable.

Further, it is assumed that the output transistor has a long and narrow shape formed so as to be long in the extension direction of the data line 32 and short in the extension direction of the scanning line 31. In such a case, with the channel width of the output transistor, a width of a unit circuit, which constitutes the scanning line drive circuit 147 of the comparative example, in the extension direction of the data line 32 also becomes wide. Thus, an interval between scanning lines 31 is widened, so that precision of display is lowered.

Accordingly, in the scanning line drive circuit 147 of the comparative example, the output transistor is formed so that a channel is formed so as to be folded. However, the output transistor having such a folded shape has a problem that light that cures a seal material hardly reaches a center part of the output transistor. Thus, in the scanning line drive circuit 147 of the comparative example, the sixth transistor Tr6 which is the output transistor is arranged on the outer side of the seal region 141.

As illustrated in FIG. 14(b), in Embodiment 1 of the invention, the scanning line drive circuit 47 is arranged so that the sixth transistor Tr6 which is the output transistor is on an inner side of the seal region 41. This is because the first relay wire 166, the second relay wire 167, and the initialization wire 168 according to Embodiment 1 of the invention are formed by the additional wire layer 27, and thus do not need to circumvent the sixth transistor Tr6 and are able to cross the sixth transistor Tr6.

The first relay wire 166, the second relay wire 167, and the initialization wire 168 according to Embodiment 1 of the invention are able to cross the sixth transistor Tr6. Thus, the sixth transistor Tr6 which is the output transistor is able to have a long and narrow shape formed so as to be short in the extension direction of the data line 32 and long in the extension direction of the scanning line 31. Since a width of the sixth transistor Tr6 in the extension direction of the data line 32 is narrow (for example, 40 μm or less), light from the light transmission portion around the sixth transistor Tr6 easily reaches the center of the sixth transistor Tr6. In the scanning line drive circuit 47 according to Embodiment 1 of the invention, the sixth transistor Tr6 which is the output transistor is able to be arranged on the inner side of the seal region 41.

Thus, as clear from FIGS. 14(a) and (b), the drive circuit region 45 according to Embodiment 1 of the invention is able to be reduced compared to the drive circuit region 145 of the comparative example by a width D in the extension direction of the scanning line 31. The reduction of the drive circuit region 45 is able to reduce an external form of the matrix substrate 20. Alternatively, it is possible to ensure a margin region in the peripheral region 40. When the margin region is provided on an outer side (opposite to the display region 30) of the seal region 41, redundancy for defect (crack, breakage) of the external form of the matrix substrate 20 is able to be enhanced. When the margin region is provided on an inner side (display region 30 side) of the drive circuit region 45, it is possible to arrange a numbering pattern for specifying a number by which the scanning line 31 is specified or arrange a protection circuit as a countermeasure against electro-static discharge (ESD).

Note that, the widths of the seal regions 141 and 41 where the seal 11 is formed affect mechanical strength of the seal 11 that is formed. Thus, values of the widths of the seal regions 141 and 41 in the comparative example and Embodiment 1 of the invention are close or the same. Further, the sixth transistor Tr6 is arranged only on the inner side of the seal region 41 in Embodiment 1, but there is no limitation thereto. For example, the sixth transistor Tr6 may include a part arranged on the inner side of the seal region 41 and a part arranged on the outer side of the seal region 41.

### (Effect)

With the configuration according to Embodiment 1, the first relay wire 66, the second relay wire 67, and the initialization wire 68 are formed by the additional wire layer 27, and thus do not need to circumvent the transistors Tr1 to Tr6. Therefore, the first relay wire 66, the second relay wire 67, and the initialization wire 68 are able to cross, be overlapped with, or planarly contact the transistors Tr1 to Tr6. This makes it possible to increase a degree of freedom in circuit arrangement of the scanning line drive circuit 47.

For example, the sixth transistor Tr6 which is the output transistor is able to have a long and narrow shape. Thereby, the sixth transistor Tr6 is able to be arranged on the inner side of the seal region 41, thus making it possible to reduce an area of the drive circuit region 45.

Note that, though all of the first relay wire 66, the second relay wire 67, and the initialization wire 68 are formed by the additional wire layer 27 in the present embodiment, only a part of the first relay wire 66, the second relay wire 67, and the initialization wire 68 may be formed by the additional wire layer 27. Further, the first relay wire 66, the second relay wire 67, and the initialization wire 68 cross only the sixth transistor Tr6, but may cross, be overlapped with, or planarly contact the other transistors Tr1 to Tr5.

### EXAMPLE

The configuration according to Embodiment 1 of the invention is applicable to a small-to-medium sized display device having enhanced definition and is advantageous.

The configuration of the comparative example and the configuration according to Embodiment 1 of the invention that are illustrated in FIG. 14 are applied to, for example, an active matrix substrate corresponding to pixels arranged in a vertical stripe manner with a pixel pitch of 10 μm×30 μm. In the comparative example and the example, an interval between the data lines 32 is 10 μm and an interval between the scanning lines 31 is 30 μm. A width of the unit circuit 50 is 30 μm×2=60 μm.

The width of the gate electrode of the sixth transistor Tr6 in the extension direction of the data line 32 is 15 μm.

The drive circuit region 45 where the scanning line drive circuit 47 is arranged in the example is reduced compared to that in the comparative example by D=45 μm as the width in the extension direction of the scanning line 31.

### Embodiment 2

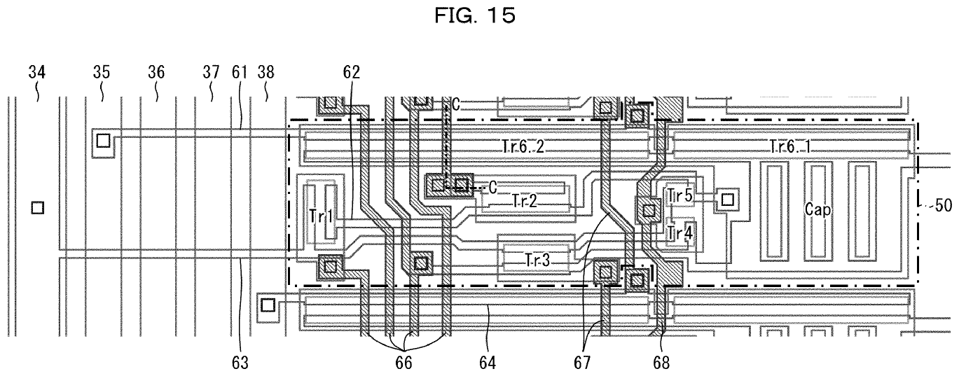

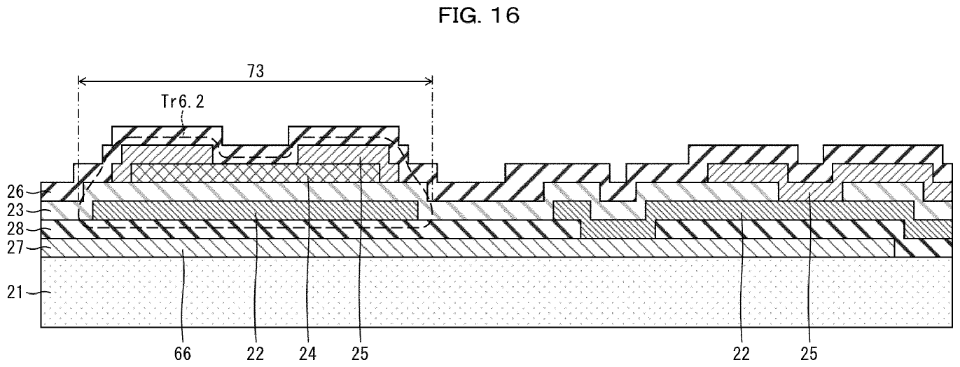

Another embodiment of the invention will be described as follows with reference to FIGS. 15 and 16. Note that, for convenience of description, members having the same functions as those of the members described in the aforementioned embodiment will be given the same reference signs and description thereof will be omitted.

The matrix substrate 20 according to Embodiment 2 is different from the matrix substrate 20 according to Embodiment 1 in the following two points, but is the same as the matrix substrate 20 according to Embodiment 1 in the other configurations. First, differently from Embodiment 1, the additional wire layer 27 and the second interlayer insulating film 28 are layered between the insulating substrate 21 and the gate layer 22 in Embodiment 2. Secondly, differently from Embodiment 1, no reconnection portion 71 is arranged and a wire or an electrode formed by the gate layer 22 is directly connected to a wire or an electrode formed by the source layer 25 in Embodiment 2.

FIG. 15 is a plan view schematically illustrating circuit arrangement of the unit circuit 50 according to Embodiment 2.

As illustrated in FIG. 15, the unit circuit 50 according to Embodiment 2 has the same configuration as that of the unit circuit 50 according to Embodiment 1 illustrated in FIG. 3 except that no reconnection portion 71 is provided.

FIG. 16 is a sectional view taken along a line C-C of FIG. 15 and a sectional view illustrating a schematic configuration of the overlapping portion 73 and a part where the gate electrode of the second transistor Tr2 is connected to the first relay wire 66 and the gate electrode of the second transistor Tr2. The overlapping portion 73 illustrated in FIG. 16 is a crossing portion where the transistor Tr6.2 included in the sixth transistor Tr6 crosses the first relay wire 66.

As illustrated in FIG. 16, in the overlapping portion 73, the first relay wire 66 formed by the additional wire layer 27 crosses the transistor Tr6.2. Further, though the semiconductor layer 24 is layered between the gate layer 22 and the additional wire layer 27 in the configuration illustrated in FIG. 12, the gate layer 22 is layered between the additional wire layer 27 and the semiconductor layer 24 in the configuration illustrated in FIG. 16. Thus, it is possible to further reduce an erroneous operation of the sixth transistor Tr6 caused by a back gate effect by which the first relay wire 66 and the second relay wire 67 that are formed by the additional wire layer 27 function as a back gate.

Further, two insulating films of the second interlayer insulating film 28 and the gate insulating film 23 are layered between the additional wire layer 27 and the source layer 25. Thus, capacity of an overlapping portion where (i) the first relay wire 66, the second relay wire 67, and the initialization wire 68 that are formed by the additional wire layer 27 and (ii) the branch wires 61 to 64 formed by the source layer 25 and the electrodes are overlapped is smaller than that of Embodiment 1. Since the capacity of the overlapping portion is reduced, a signal waveform is aligned so that a waveform of the output Out(n) of the unit circuit 50 is able to be stabilized.

### (Comparison)

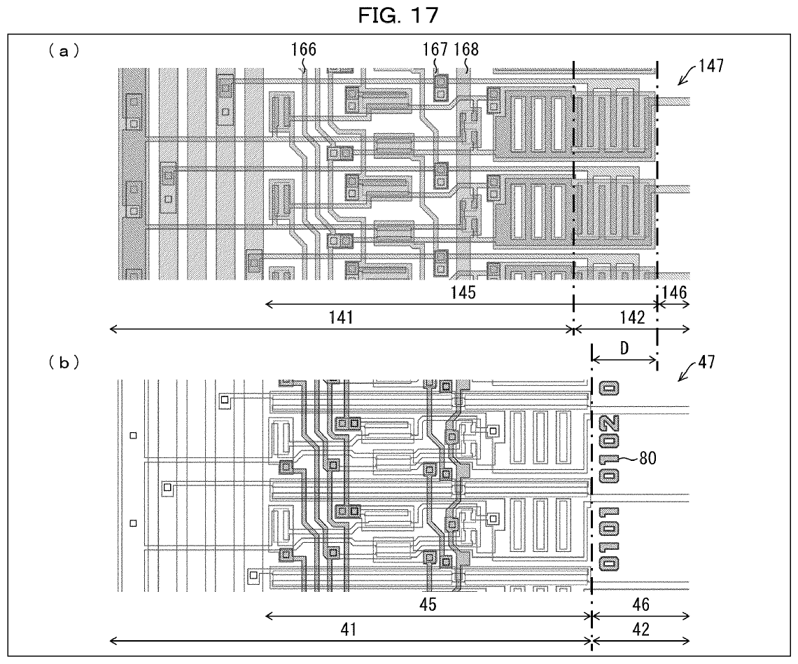

FIG. 17 is a view in which (a) the scanning line drive circuit 147 of the comparative example and (b) the scanning line drive circuit 47 according to Embodiment 2 of the invention are compared.

The scanning line drive circuit 147 of the comparative example has a configuration including neither the additional wire layer 27 nor the second interlayer insulating film 28. Thus, in the conventional scanning line drive circuit 147, the first relay wire 166, the second relay wire 167, and the initialization wire 168 are formed by the gate layer 22. Accordingly, the scanning line drive circuit 147 of the comparative example and the scanning line drive circuit 47 according to Embodiment 1 of the invention are different in circuit arrangement, but are the same in a circuit configuration.

As illustrated in FIG. 17(a), in the comparative example, the scanning line drive circuit 147 is arranged so that the sixth transistor Tr6 which is the output transistor is on the outer side of the seal region 141. On the other hand, as illustrated in FIG. 17(b), in Embodiment 2 of the invention, the scanning line drive circuit 47 is arranged so that the sixth transistor Tr6 which is the output transistor is on the inner side of the seal region 41, similarly to Embodiment 1.

Thus, as clear from FIGS. 17(a) and (b), the drive circuit region 45 according to Embodiment 1 of the invention is able to be reduced compared to the drive circuit region 145 of the comparative example by the width D in the extension direction of the scanning line 31. The reduction of the drive circuit region 45 is able to reduce the external form of the matrix substrate 20. Alternatively, it is possible to ensure a margin region in the peripheral region 40. When the margin region is provided on the outer side (opposite to the display region 30) of the seal region 41, redundancy for defect (crack, breakage) of the external form of the matrix substrate 20 is able to be enhanced. When the margin region is provided on the inner side (display region 30 side) of the drive circuit region 45, it is possible to arrange a numbering pattern 80 for specifying a number by which the scanning line 31 is specified.

### (Effect)

With the configuration according to Embodiment 2 of the invention, similarly to the configuration according to Embodiment 1 of the invention, it is possible to increase a degree of freedom in circuit arrangement of the scanning line drive circuit 47. Further, with the configuration according to Embodiment 2 of the invention, compared to the configuration according to Embodiment 1, it is possible to further reduce an erroneous operation of the sixth transistor Tr6 (output transistor) caused by a back gate effect. Further, with the configuration according to Embodiment 2 of the invention, compared to the configuration according to Embodiment 1, it is possible to stabilize the waveform of the output Out(n) of the unit circuit 50.

### Embodiment 3

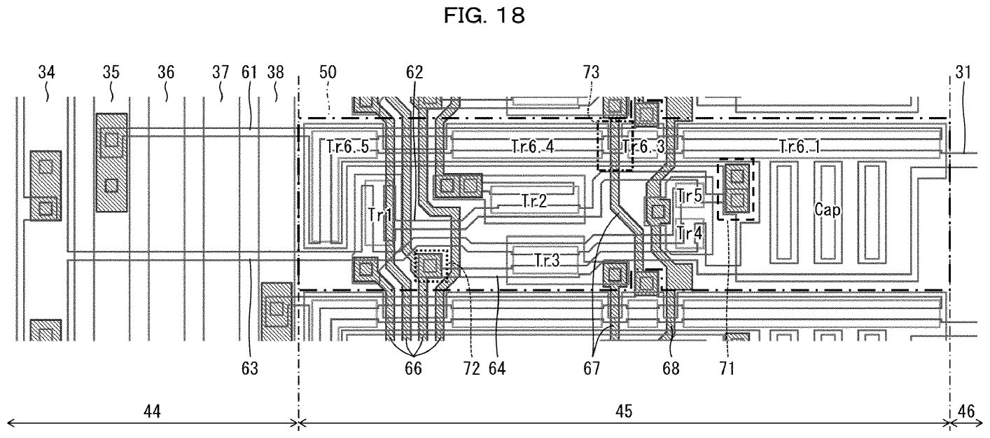

Another embodiment of the invention will be described as follows with reference to FIG. 18. Note that, for convenience of description, members having the same functions as those of the members described in the aforementioned embodiments will be given the same reference signs and description thereof will be omitted.

FIG. 18 is a plan view schematically illustrating circuit arrangement of the unit circuit 50 according to Embodiment 3.

The matrix substrate 20 according to Embodiment 3 is obtained by changing arrangement of the first transistor Tr1 and the first relay wire 66 in the matrix substrate 20 according to Embodiment 1 as a shape of the sixth transistor Tr6 is changed. The matrix substrate 20 according to Embodiment 3 is the same as the matrix substrate 20 according to Embodiment 1 in the other configurations.

As illustrated in FIG. 18, the sixth transistor Tr6 according to Embodiment 3 is divided not only by the initialization wire 68 but also by the first relay wire 66 and the second relay wire 67. Thus, the sixth transistor Tr6 according to Embodiment 3 is a transistor group including four transistors of (i) a transistor Tr6.1 on a right side (display region 30 side) of the initialization wire 68 in FIG. 18, (ii) a transistor 6.3 between the initialization wire 68 and the second relay wire 67, (iii) a transistor 6.4 between the second relay wire 67 and the first relay wire 66, and (iv) a transistor Tr6.5 on a left side (opposite to the display region 30) of the first relay wire 66 in FIG. 18. The sixth transistor Tr6 according to Embodiment 3 further includes the bonding wire 51 by which gate electrodes are bonded, the bonding wire 52 by which source electrodes are bonded, and the bonding wire 53 by which drain electrodes are bonded (i) between the transistor Tr6.1 and the transistor Tr6.3, (ii) between the transistor Tr6.3 and the transistor Tr6.4, and (iii) between the transistor Tr6.4 and the transistor Tr6.5.

Thus, the first relay wire 66, the second relay wire 67, and the initialization wire 68 are (i) overlapped with the bonding wires 51 to 53 and (ii) not overlapped with the transistor Tr6.1, Tr6.3, Tr6.4, or Tr6.5. As a result, it is possible to further reduce an erroneous operation of the sixth transistor Tr6 caused by a back gate effect by which the first relay wire 66, the second relay wire 67, and the initialization wire 68 function as a back gate.

The channel width of the sixth transistor Tr6 according to Embodiment 3 in the extension direction of the scanning line 31 is significantly shorter than an overall length of the sixth transistor Tr6, because the sixth transistor Tr6 is also divided by the first relay wire 66 and the second relay wire 67. Thus, to ensure the channel width of the sixth transistor Tr6, the sixth transistor Tr6 according to Embodiment 3 is formed into an L-shaped folded line shape. With respect to the width of the unit circuit 50 in the extension direction of the scanning line 31, the overall length of the sixth transistor Tr6 in the folded line shape according to Embodiment 3 is longer than that of the sixth transistor Tr6 (refer to FIG. 5) in the linear shape according to Embodiment 1. Thus, the channel width of the sixth transistor Tr6 according to Embodiment 3 is ensured to be sufficiently wide as the output transistor.

As illustrated in FIG. 18, further, the first transistor Tr1 and the first relay wire 66 are also slightly moved compared to Embodiment 1 (refer to FIG. 5) as the sixth transistor Tr6 is deformed. Specifically, the first transistor Tr1 according to Embodiment 3 is slightly moved to the display region 30 (from the left side to the right side in FIG. 18) compared to the first transistor Tr1 according to Embodiment 1. Further, first relay wires 66 according to Embodiment 3 are provided so that an interval between the first relay wires 66 is narrower than that of first relay wires 66 according to Embodiment 1. Furthermore, the first relay wire that supplies the output Out(n+2) of the unit circuit 50 on the (n+2)th stage is overlapped with the drain electrode of the first transistor Tr1 of the unit circuit 50 on the nth stage.

### (Effect)

With the configuration according to Embodiment 3 of the invention, similarly to the configuration according to Embodiment 1 of the invention, it is possible to increase a degree of freedom in circuit arrangement of the scanning line drive circuit 47. Further, with the configuration according to Embodiment 3 of the invention, compared to the configuration according to Embodiment 1, it is possible to further reduce an erroneous operation of the sixth transistor Tr6 (output transistor) caused by a back gate effect.

### (Conclusion)

A drive circuit (scanning line drive circuit 47) according to an aspect 1 of the invention includes: a plurality of unit circuits (50) that drive a plurality of output lines (scanning lines 31); and a first-type wire (first relay wire 66, second relay wire 67, initialization wire 68) that connects the unit circuits and is formed by a first conductive layer (additional wire layer 27), in which a unit circuit includes a circuit element group (transistors Tr1 to Tr6, bootstrap capacitor Cap), at least one circuit element group (first transistor Tr1, sixth transistor Tr6) includes a single unit circuit (first transistor Tr1) that has an electrode (gate electrode, drain electrode, source electrode) formed by (i) a second conductive layer (gate layer 22) different from the first conductive layer or (ii) a third conductive layer (source layer 25) different from the first conductive layer or the second conductive layer or includes (i) a plurality of circuit elements (transistors Tr6.1 and Tr6.2, transistors Tr6.1 and Tr6.3 to Tr6.5) connected in parallel and (ii) a second-type wire (bonding wires 51 to 53) that connects an electrode of the circuit element included in the circuit element group to an electrode of another circuit element included in the circuit element group and is formed by the second conductive layer or the third conductive layer, and the at least one circuit element group is overlapped or in contact with at least one first-type wire in plan view. (The sixth transistor Tr6 according to Embodiments 1 to 3 is overlapped with the first relay wire 66, the second relay wire 67, and the initialization wire 68. The first transistor Tr1 according to Embodiment 3 is overlapped with the first relay wire 66.)

According to the aforementioned configuration, the first-type wire that connects the unit circuits is formed by the first conductive layer. Further, (i) the electrode of the circuit element and (ii) the second-type wire that connects the electrodes of the circuit elements included in the same circuit element group are formed by the second conductive layer or the third conductive layer each of which is different from the first conductive layer. Thus, the circuit element group is able to be overlapped or in contact with the first-type wire in plan view. Because overlapping or contact is allowed, the first-type wire does not need to circumvent the circuit element group, and the drive circuit in which a degree of freedom in arrangement of the first-type wire and the circuit element group is high is able to be achieved. This makes it easy to reduce an area of the drive circuit or change a shape thereof.

In recent years, a gate driver monolithic (GMD) technique of monolithically forming a scanning line drive circuit in a matrix substrate has become widespread. In such a matrix substrate, by reducing an area of the scanning line drive circuit, an area of a peripheral region around a display region is able to be reduced and a frame size of a display device is able to be reduced. Alternatively, it is possible to provide a margin region, in which no scanning drive circuit is formed, around the peripheral region or expand the margin region. Such a margin circuit region is advantageous when a protection circuit as a countermeasure against ESD (electro-static discharge) is arranged, a numbering pattern for specifying a scanning signal line is formed, or a margin for a defect such as crack or breakage of an external form of an insulating substrate is ensured.

Thus, according to the aforementioned configuration, it is possible to achieve the scanning line drive circuit that is suitable for being monolithically formed in the matrix substrate.

The drive circuit (scanning line drive circuit 47) according to an aspect 2 of the invention may have a configuration in which the circuit element group (transistors Tr1 to Tr6, bootstrap capacitor Cap) includes a transistor group (transistors Tr1 to Tr6) including a transistor as the circuit element, and in a case of the transistor group (sixth transistor Tr6) including a plurality of transistors, a gate electrode of a transistor (transistors Tr6.1 and Tr6.2, transistors 6.1 and Tr6.3 to Tr6.5) included in the transistor group is connected to a gate electrode of a different transistor included in the transistor group by the second-type wire, a drain electrode of the transistor included in the transistor group is connected to a drain electrode of the different transistor included in the transistor group by the second-type wire, and a source electrode of the transistor included in the transistor group is connected to a source electrode of the different transistor included in the transistor group by the second-type wire, in the aspect 1.

According to the aforementioned configuration, the plurality of transistors connected in parallel in the transistor group have gate electrodes connected to each other, source electrodes connected to each other, and drain electrodes connected to each other each by the second-type wire. Thus, the plurality of transistors connected in parallel function as one transistor. Thereby, regardless of whether the transistor group includes a single transistor or multiple transistors, the transistor group is able to be treated as one transistor.

The drive circuit (scanning line drive circuit 47) according to an aspect 3 of the invention may have a configuration in which at least one transistor group (sixth transistor Tr6) includes the plurality of transistors, and is overlapped with the at least one first-type wire (first relay wire 66, second relay wire 67, initialization wire 68) in plan view so that the first-type wire is overlapped with the second-type wire (bonding wires 51 to 53), in the aspect 2.

According to the aforementioned configuration, the first-type wire is overlapped with the transistor element group so that the first-type wire is overlapped with the second-type wire. Thus, it is possible to reduce or eliminate a region where the first-type wire is overlapped with a transistor. Since a wire is generally thinner than a gate electrode, a drain electrode, a source electrode, and a channel region of a transistor, interaction is small in a case of overlapping with the wire compared to a case of overlapping with the transistor. Therefore, interaction of the first-type wire and the transistor group is able to be reduced. As a result, it is possible to reduce (i) load capacity between the first-type wire and the transistor group and (ii) an erroneous operation of the transistor group caused by a back gate effect by which the first-type wire functions as a back gate of the transistor. The reduction of the load capacity is advantageous to reduce a signal rounding, in particular, when the first-type wire is formed commonly in all unit circuits (in a case of an initialization wire or the like).

The drive circuit (scanning line drive circuit 47) according to an aspect 4 of the invention may have a configuration in which a semiconductor layer (24) that forms a channel of the transistor is separated for each of the transistors, and the first-type wire (first relay wire 66, second relay wire 67, initialization wire 68) is overlapped with the at least one transistor group (sixth transistor) so as to be overlapped with the second-type wire (bonding wires 51 to 53) and not overlapped with the semiconductor layer (24) forming the channel of the transistor, in the aspect 3.

According to the aforementioned configuration, the semiconductor layer forming the channel of the transistor is separated for each of the transistors, and the first-type wire overlapped with the transistor group is overlapped with the second-type wire but not overlapped with the semiconductor layer forming the channel of the transistor. Thereby, it is possible to further reduce an erroneous operation of the transistor group caused by a back gate effect by which the first-type wire functions as a back gate of the transistor.

The aforementioned configuration is, in other words, a configuration in which a semiconductor layer (24) that forms a channel of the transistor is separated for each of the transistors, and the first-type wire (first relay wire 66, second relay wire 67, initialization wire 68) is overlapped with the at least one transistor group (sixth transistor) so as to be overlapped only with the second-type wire (bonding wires 51 to 53), in the aspect 3.

The drive circuit (scanning line drive circuit 47) according to an aspect 5 of the invention may have a configuration in which the first conductive layer (additional wire layer 27), an insulating film (second interlayer insulating film 28), the second conductive layer (gate layer 22), an insulating film (gate insulating film 23), the semiconductor layer (24), and the third conductive layer (source layer 25) are layered in this order on an insulating substrate (21), and in the transistor group (first transistor Tr1, sixth transistor Tr6) that is overlapped or in contact with the at least one first-type wire, the gate electrode of the transistor is formed by the second conductive layer, the drain electrode and the source electrode of the transistor are formed by the third conductive layer, and the channel of the transistor is formed by the semiconductor layer, in any one aspect of the aspects 2 to 4.

According to the aforementioned configuration, the second conductive layer forming the gate electrode is layered between the first conductive layer forming the first-type wire and the semiconductor layer forming the channel. Thus, it is possible to reduce an erroneous operation of the transistor group, which is overlapped with the first-type wire, caused by a back gate effect by which the first-type wire functions as a back gate.

The drive circuit (scanning line drive circuit 47) according to an aspect 6 of the invention may have a configuration in which the first conductive layer (additional wire layer 27), an insulating film (second interlayer insulating film 28), the second conductive layer (gate layer 22), an insulating film (gate insulating film 23), and the third conductive layer (source layer 25) are layered in this order or the second conductive layer, the insulating film, the third conductive layer, the insulating film, and the first conductive layer are layered in this order on an insulating substrate (21), in any one aspect of the aspects 1 to 5.

According to the aforementioned configuration, since the first conductive layer is not held between the second conductive layer and the third conductive layer, interaction between an electrode and a wire which are formed by the first conductive layer and an electrode and a wire which are formed by the second conductive layer or the third conductive layer is able to be reduced. Thus, it is possible to further reduce an erroneous operation of the transistor group, which is overlapped with the first-type wire, caused by a back gate effect by which the first-type wire functions as a back gate.

The drive circuit (scanning line drive circuit 47) according to an aspect 7 of the invention may have a configuration in which the first-type wire includes a first relay wire (66) that supplies, to one (unit circuit 50 on nth stage) of the unit circuits, an output of another one (unit circuit 50 on (n+4)th stage, unit circuit 50 on (n−4)th stage) of the unit circuits, in any one aspect of the aspects 1 to 6.

According to the aforementioned configuration, the unit circuit is able to supply an output of another unit circuit. Thus, for example, a flip-flop circuit is usable as the unit circuit, so that the drive circuit is able to function as a shift register.

The drive circuit (scanning line drive circuit 47) according to an aspect 8 of the invention may have a configuration in which the first-type wire includes a second relay wire (67) that supplies, to one (unit circuit 50 on nth stage) of the unit circuits, an input of another one (unit circuit 50 on (n+4)th stage) of the unit circuits, in any one aspect of the aspects 1 to 7.

According to the aforementioned configuration, the unit circuit is able to supply an input of another unit circuit. Thus, a degree of freedom in connection between a trunk wire and the unit circuit to perform an input to the drive circuit is able to be increased. For example, it is possible to branch the second relay wire from a branch wire by which a circuit element is connected to a trunk wire and branch the second relay wire from an electrode of the circuit element connected to the trunk wire.

The drive circuit (scanning line drive circuit 47) according to an aspect 9 of the invention may have a configuration in which the first-type wire includes an initialization wire (68) that supplies an initialization signal (Reset) for initializing the unit circuit (50), in any one aspect of the aspects 1 to 8.

According to the aforementioned configuration, the drive circuit is able to be initialized by the initialization signal.

A matrix substrate (20) according to an aspect 10 of the invention has a configuration including an insulating substrate (21) that has a peripheral region (40) where the drive circuit (scanning line drive circuit 47)) according to any one aspect of the aspects 1 to 9 and a trunk wire (34 to 38) that supplies an input to the drive circuit are arranged, and a display region (30) where the output lines are arranged as scanning lines (31).

A matrix substrate (20) according to an aspect 11 of the invention includes an insulating substrate (21) that has a display region (30) where a plurality of scanning lines (31) are arranged, and a peripheral region (40) where (i) a drive circuit (scanning line drive circuit 47) that includes a plurality of unit circuits (50) that drive the scanning lines and a first-type wire (first relay wire 66, second relay wire 67, initialization wire 68) that connects the unit circuits and is formed by a first conductive layer (additional wire layer 27) and (ii) a trunk wire (34 to 38) that supplies an input to the drive circuit are arranged, in which at least one of the unit circuits includes a circuit element group (transistors Tr1 to Tr6, bootstrap capacitor Cap), the circuit element group includes a single circuit element that has an electrode formed by (i) a second conductive layer (gate layer 22) different from the first conductive layer or (ii) a third conductive layer (source layer 25) different from the first conductive layer or the second conductive layer or includes (i) a plurality of circuit elements connected in parallel and (ii) the second-type wire (bonding wires 51 to 53) that connects electrodes of the circuit element included in the circuit element group and is formed by the second conductive layer or the third conductive layer, and at least one circuit element group is overlapped or in contact with at least one first-type wire in plan view. (The sixth transistor Tr6 according to Embodiments 1 to 3 is overlapped with the first relay wire 66, the second relay wire 67, and the initialization wire 68. The first transistor Tr1 according to Embodiment 3 is overlapped with the first relay wire 66.)

With the configuration according to the aspect 10 or 11, it is possible to achieve the matrix substrate in which the drive circuit according to any one aspect of the aspects 1 to 9 drives the scanning lines.

The matrix substrate (20) according to an aspect 12 of the invention may have a configuration in which the peripheral region (40) includes a seal region (41) where a seal (11) by which an electrooptical substance (liquid crystal 12) is enclosed is formed, and in the seal region, a top layer of lamination including the first conductive layer (additional wire layer 27), the second conductive layer (gate layer 22), and the third conductive layer (source layer 25) that are layered on the insulating substrate (21) is an insulating film (second interlayer insulating film 28, first interlayer insulating film 26), in the aspect 10 or 11.

According to the aforementioned configuration, the top layer of the lamination in the seal region is the insulating layer. Thus, it is possible to prevent disconnection by a spacer included in a seal material. In particular, in order to use a liquid crystal display device of a TN (twisted nematic) system or a VA (vertical aligned) system, in a case where a spacer in which conductive particles are mixed is used to achieve conductivity with a counter electrode provided on a counter substrate, short-circuit caused by the conductive particles is able to be prevented.

Therefore, the drive circuit and/or the trunk wire is able to be partially arranged in the seal region. This makes it possible to reduce an area of the peripheral region compared to a case where the drive circuit and the trunk wire are arranged only outside the seal region.

The matrix substrate (20) according to an aspect 13 of the invention may have a configuration in which at least one of the unit circuits (50) includes an output transistor group (sixth transistor Tr6), which drives a corresponding scanning line, as one circuit element group, and when the output transistor group includes a single transistor, one of a source electrode and a drain electrode of the transistor is connected to a corresponding scanning line, and when the output transistor group includes a plurality of transistors, one of a source electrode and a drain electrode of at least one (transistor Tr6.1) of the transistors is connected to a corresponding scanning line, in any one aspect of the aspects 10 to 12.

According to the aforementioned configuration, since the output transistor group is able to be overlapped or in contact with the first-type wire in plan view, a degree of freedom in arrangement of at least the output transistor group is high.

The output transistor group drives the scanning line, and thus preferably has small channel resistance when a state between a source and a drain is conductive. As the channel resistance is small, current flowing between the source and the drain increases and a voltage drop between the source and the drain is reduced. Thus, as the channel resistance of the output transistor group is small, the drive circuit is resistant to the output resistance and a rounding of an output signal is able to be reduced. For example, in a case where the drive circuit drives the scanning line of the matrix substrate as the output line, in order to achieve sufficiently high capability of being charged to the scanning line, the output transistor group preferably has small channel resistance when the state between the source and the drain is conductive. In this manner, to reduce the channel resistance, the output transistor group tends to be larger than a circuit element group other than the output transistor group. Thus, the high degree of freedom in arrangement of the output transistor group is particularly advantageous.

Conventionally, the conductive layer forming the electrodes of the circuit element group and the conductive layer forming the first-type wire that connects the unit circuits are common. Therefore, the circuit element group is not able to be overlapped or in contact with the first-type wire. Thus, conventionally, the output transistor group has a large area and is not overlapped or in contact with the wire in plan view. Additionally, a photosetting material is often used for a seal material forming a seal by which an electrooptical substance such as liquid crystal is enclosed. Thus, a transmission portion by which light that cures the seal material is able to be transmitted is provided in a region where the seal is formed.

Therefore, conventionally, the drive circuit and the trunk wire are laid out so that, in the peripheral region of the matrix substrate, (i) the output transistor group is arranged on a display region side, (ii) the trunk wire is arranged opposite to the display region, and (iii) the circuit element group other than the output transistor group is arranged between the output transistor group and the trunk wire. The output transistor group is arranged outside the region where the seal is formed.

In recent years, for reducing an area (frame size) of the peripheral region, it has been desired that the output transistor group is arranged in the region where the seal is formed. However, in a case where the output transistor group has a long and narrow shape so that light transmitted through the light transmission portion is able to cure the seal material on a center part of an output transistor, there is a problem that the first-type wire that connects the unit circuits is difficult to be arranged. This is because the first-type wire (relay wire and initialization wire) is conventionally formed by any of a second conductive layer group forming electrodes of an output TFT group.

According to the aforementioned configuration, the output transistor group is able to be overlapped or in contact with the first-type wire in plan view. Thus, even when the output transistor group having a long and narrow shape is arranged in the region where the seal is formed, the first-type wire is able to be easily arranged. Note that, the first conductive layer forming the first-type wire may be a conductive layer forming a pixel electrode or a conductive layer forming a common electrode for liquid crystal display of an FFS (fringe field switching) system, but is preferably a conductive layer other than them. This is because the conductive layer forming the pixel electrode or the common electrode of the FFS system is generally a metal oxide transparent conductive layer and has high resistance as a wire. There is also a matrix substrate in which a protection film is not formed on (a side opposite to a counter substrate of) the conductive layer forming the pixel electrode or the common electrode of the FFS system. In such a matrix substrate, a conductive layer below the conductive layer forming the pixel electrode or the common electrode of the FFS system is preferably a first conductive layer to prevent disconnection by a spacer in a seal.

The matrix substrate (20) according to an aspect 14 of the invention may have a configuration in which the peripheral region (40) includes a seal region (41) where a seal (11) by which an electrooptical substance (liquid crystal 12) is enclosed is formed, and the output transistor group (sixth transistor Tr6) is at least partially arranged in the seal region, in the aspect 13.

According to the aforementioned configuration, the output transistor group is at least partially arranged in the seal region. Therefore, compared to a case where the output transistor group is arranged only in a region where the seal is not formed in the peripheral region, it is possible to reduce an area of the peripheral region and expand the seal region.

Note that, a rate at which the output transistor group is arranged in the seal region is preferably high. Further, a whole of the output transistor group is more preferably arranged in the seal region.

The matrix substrate (20) according to an aspect 15 of the invention may have a configuration in which a shape of the output transistor group (sixth transistor group Tr6) is long and narrow in a direction in which the scanning lines (31) extend, in the aspect 14.

According to the aforementioned configuration, since the shape of the output transistor group is long and narrow, light from the light transmission portion around the output transistor group easily reaches a center part of the output transistor group. A photosetting material is often used for the seal material used for forming the seal. Thus, it is advantageous that the light easily reaches the center part of the output transistor group. Further, since the shape of the output transistor group is long and narrow in the direction in which the scanning lines extend, application to a drive circuit in which a width of the unit circuit is narrow in a direction of data lines crossing the scanning lines is possible.

For example, the shape of the output transistor is preferably a linear shape. The shape is also preferably an L-shaped folded line shape. The folded line shape is more easily elongated than the linear shape and thus easily expands a channel width.

A display device (liquid crystal display panel 100) according to an aspect 16 of the invention may have a configuration of including the matrix substrate (20) in any one aspect of the aspects 10 to 15.

According to the aforementioned configuration, it is possible to achieve the display device including the matrix substrate according to any one aspect of the aspects 10 to 15.

The invention is not limited to each of the embodiments described above, and may be modified in various manners within the scope indicated in the claims and an embodiment achieved by appropriately combining technical means disclosed in each of different embodiments is also encompassed in the technical scope of the invention. Further, by combining the technical means disclosed in each of the embodiments, a new technical feature may be formed.

### REFERENCE SIGNS LIST

10 counter substrate
11 seal
12 liquid crystal
20 matrix substrate
21 insulating substrate
22 gate layer (second conductive layer)
23 gate insulating film
24 semiconductor layer
25 source layer (third conductive layer)
26 first interlayer insulating film
27 additional wire layer (first conductive layer)
28 second interlayer insulating film
29 contact hole
30 display region
31 scanning line (output line)
32 data line
34 low-potential trunk wire (trunk wire)
35 first clock trunk wire (trunk wire)
36 second clock trunk wire (trunk wire)
37 third clock trunk wire (trunk wire)
38 fourth clock trunk wire (trunk wire)
40 peripheral region
41, 141 seal region
44 trunk wire region
45, 145 drive circuit region
47, 147 scanning line drive circuit
48 data line drive circuit
49 terminal portion
50 unit circuit
51, 52, 53 bonding wire (second-type wire)
61 first branch wire
62 second branch wire
63 third branch wire
64 fourth branch wire
66, 166 first relay wire (first-type wire)
67, 167 second relay wire (first-type wire)
68, 168 initialization wire (first-type wire)
72 connection portion
73 overlapping portion
80 numbering pattern
100 liquid crystal display panel
CK1 first clock signal (input)
CK2 second clock signal (input)
CK3 third clock signal (input)
CK4 fourth clock signal (input)
Reset initialization signal
Tr1 first transistor
Tr2 second transistor
Tr3 third transistor
Tr4 fourth transistor
Tr5 fifth transistor
Tr6 sixth transistor
Vss low potential (input)

1: A drive circuit comprising: a plurality of unit circuits that drive a plurality of output lines; and a first-type wire that connects the unit circuits and is formed by a first conductive layer, wherein
at least one of the unit circuits includes a circuit element group,
the circuit element group
includes a single circuit element that has an electrode formed by (i) a second conductive layer different from the first conductive layer or (ii) a third conductive layer different from the first conductive layer or the second conductive layer or
includes (i) a plurality of circuit elements connected in parallel and (ii) a second-type wire that connects an electrode of the circuit element included in the circuit element group to an electrode of another circuit element included in the circuit element group and is formed by the second conductive layer or the third conductive layer, and
at least one circuit element group is overlapped or in contact with at least one first-type wire in plan view.

2: The drive circuit according to claim 1, wherein
the circuit element group includes a transistor group including a transistor as the circuit element, and
in a case of the transistor group including a plurality of transistors,
a gate electrode of a transistor included in the transistor group is connected to a gate electrode of a different transistor included in the transistor group by the second-type wire,
a drain electrode of the transistor included in the transistor group is connected to a drain electrode of the different transistor included in the transistor group by the second-type wire, and
a source electrode of the transistor included in the transistor group is connected to a source electrode of the different transistor included in the transistor group by the second-type wire.

3: The drive circuit according to claim 2, wherein
at least one transistor group
includes the plurality of transistors, and
is overlapped with the at least one first-type wire in plan view so that the first-type wire is overlapped with the second-type wire.

4: The drive circuit according to claim 3, wherein
a semiconductor layer that forms a channel of the transistor is separated for each of the transistors, and
the first-type wire is overlapped with the at least one transistor group so as to be overlapped with the second-type wire and not overlapped with the semiconductor layer forming the channel of the transistor.

5: The drive circuit according to claim 2, wherein
the first conductive layer, an insulating film, the second conductive layer, an insulating film, the semiconductor layer, and the third conductive layer are layered in this order on an insulating substrate, and
in the transistor group that is overlapped or in contact with the at least one first-type wire,
the gate electrode of the transistor is formed by the second conductive layer,
the drain electrode and the source electrode of the transistor are formed by the third conductive layer, and
the channel of the transistor is formed by the semiconductor layer.

6: The drive circuit according to claim 1, wherein
the first conductive layer, an insulating film, the second conductive layer, an insulating film, and the third conductive layer are layered in this order or
the second conductive layer, the insulating film, the third conductive layer, the insulating film, and the first conductive layer are layered in this order
on an insulating substrate.

7: A matrix substrate comprising
an insulating substrate that has
a peripheral region where the drive circuit according to claim 1 and a trunk wire that supplies an input to the drive circuit are arranged and
a display region where the output lines are arranged as scanning lines.

8: The matrix substrate according to claim 7, wherein
the peripheral region includes a seal region where a seal by which an electrooptical substance is enclosed is formed, and
in the seal region, a top layer of lamination including the first conductive layer, the second conductive layer, and the third conductive layer that are layered on the insulating substrate is an insulating film.

9: The matrix substrate according to claim 7, wherein
at least one of the unit circuits includes an output transistor group, which drives a corresponding output line, as one circuit element group, and
when the output transistor group includes a single transistor, one of a source electrode and a drain electrode of the transistor is connected to a corresponding scanning line, and
when the output transistor group includes a plurality of transistors, one of a source electrode and a drain electrode of at least one of the transistors is connected to a corresponding scanning line.

10: The matrix substrate according to claim 9, wherein
the peripheral region includes a seal region where a seal by which an electrooptical substance is enclosed is formed, and
the output transistor group is at least partially arranged in the seal region.

11: The matrix substrate according to claim 10, wherein a shape of the output transistor group is long and narrow in a direction in which the scanning lines extend.

12: A display device comprising the matrix substrate according to claim 7.
